(19) United States
(12) Patent Application Publication
(10) Pub. No.: US 2026/0155629 A1
(43) Pub. Date: Jun. 4, 2026

(54) HIGH-POWER, HIGH-EFFICIENCY INFRARED-EMITTING QUANTUM CASCADE LASERS

(71) Applicant: Wisconsin Alumni Research Foundation, Madison, WI (US)

(72) Inventors: Dan Botez, Madison, WI (US); Luke J. Mawst, Sun Prairie, WI (US); Suraj Suri, Madison, WI (US)

(21) Appl. No.: 18/968,530

(22) Filed: Dec. 4, 2024

(51) Int. Cl. H01S 5/34

(52) U.S. Cl. CPC H01S 5/3402; H01S 5/3416

(57) ABSTRACT

Quantum cascade lasers (QCLs) are provided, which in embodiments comprise a plurality of stages, each stage comprising alternating quantum well layers and barrier layers, wherein each stage is configured, upon application of an electric field F across the plurality of stages, to inject carriers from a low energy state of an adjacent, upstream stage of the plurality of stages into a high energy state of a lasing stage of the plurality of stages, via tunneling injection through multiple barrier layers comprising barrier layers of the adjacent, upstream stage and barrier layers of the lasing stage, wherein carriers in the lasing stage undergo intraband transitions from an upper laser level of the lasing stage to at least one lower laser level of the lasing stage with the emission of laser light and without carrier leakage.

### REFERENCE TO GOVERNMENT RIGHTS

This invention was made with government support under N6833519C0196 and N6893623C0002 awarded by the Naval Air Warfare Center Aircraft Division. The government has certain rights in the invention.

### BACKGROUND

Conventional mid-infrared (IR) quantum cascade lasers (QCLs) are rather inefficient, which makes their use in many applications difficult, if not practically impossible. For instance, for mid-wavelength IR (λ˜3-6 microns) devices, the electrical-to-optical power-conversion efficiency, i.e., the wall-plug efficiency (WPE), is generally no more than 15%. This means that in order to generate 1 Watt of mid-wavelength IR light, 5.7 Watts of heat must be removed. This makes it very difficult and costly to use such devices in practical applications, since thermal-load management drives the packaged laser system's size, weight, and overall power consumption. Some progress has been made in improving the WPEs of existing mid-IR QCLs, but the WPEs of these devices still remain below fundamental limits. In addition, neither the principle of operation of these existing devices, nor how to further improve WPE, has been understood.

### SUMMARY

The present disclosure provides quantum cascade laser (QCL) devices. The configuration of the present QCL devices is based, at least in part, on the inventors' insights gained from developing and employing a modified nonequilibrium Green's functions (NEGF)-based, interface-roughness (IFR) scattering formalism as described in detail in the Examples, below. These insights, in conjunction with conduction band engineering, IFR scattering engineering, and optimized crystal growth conditions, are leveraged to provide QCLs configured to achieve interstage carrier injection and lasing, without carrier leakage. This includes QCLs that also exhibit photon-induced carrier transport (PICT). The inventors' approach enables QCLs that achieve wall-plug efficiencies (WPEs) close to the fundamental limit for their lasing wavelengths, e.g., about 40% for mid-wavelength IR and about 25% for long-wavelength IR. Taking a mid-wavelength IR QCL as an example, this means that in order to generate 1 Watt of mid-wavelength IR light, only 1.5 Watts of heat needs to be removed. This is almost of factor of 4 lower than existing mid-wavelength IR QCL devices, a critical improvement for commercial applications of the devices. Thus, the present disclosure finally enables practical use of mid-IR QCL devices for a wide range of civilian and defense applications: e.g., missile avoidance systems, long-distance communications between low-Earth-orbit satellites and Earth; and long-distance free-space communications under adverse weather conditions.

Quantum cascade lasers (QCLs) are provided, which in embodiments comprise a plurality of stages, each stage comprising alternating quantum well layers and barrier layers, wherein each stage is configured, upon application of an electric field F across the plurality of stages, to inject carriers from a low energy state of an adjacent, upstream stage of the plurality of stages into a high energy state of a lasing stage of the plurality of stages, via tunneling injection through multiple barrier layers comprising barrier layers of the adjacent, upstream stage and barrier layers of the lasing stage, wherein carriers in the lasing stage undergo intraband transitions from an upper laser level of the lasing stage to at least one (e.g., 2) lower laser level of the lasing stage with the emission of laser light and without carrier leakage.

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings. Color versions of the figures can be found in Suri, Suraj, et al. “Modeling with graded interfaces: Tool for understanding and designing record-high power and efficiency mid-infrared quantum cascade lasers.” Nanophotonics 13.10 (2024): 1745-1757, the disclosure of which is incorporated herein for the purpose of providing color figures

FIG. 1 plots voltage- and light-current curves (500 ns pulse width; 5% duty cycle) of a 4.9 μm-emitting taper-active (TA)-type QCL vs. those obtained by using the inventors' modified NEGF modeling with graded interfaces. The employed graded-interfaces IFR-scattering parameters are: Δ=0.10 nm, 0.13 nm, and 0.17 nm for the interfaces at the lattice-matched barrier, moderately strained barriers and AlAs barriers, respectively; Λ=6 nm; L=0.4 nm; and Λ_{⊥}=0.1 nm.

FIGS. 2A and 2B show conduction-band (CB) diagrams and relevant wavefunctions for the 4.9 μm-emitting TA-type QCL, at lasing threshold: (FIG. 2A) for the whole stage; (FIG. 2B) for the low energy states in the optical transition region (i.e., states 3, 2 and 1) and the extractor states penetrating the optical transition region (i.e., states 3′, 2′ and 1′). States 3 and 3′ are the lower laser levels.

FIG. 3 shows the CB diagram and relevant wavefunctions for the 4.9 μm-emitting TA-type QCL at 1.4 times threshold. State g₄ is the upper laser level.

FIG. 4A shows normalized sheet-carrier densities and FIG. 4B shows electron temperatures, in relevant energy levels, at 66.8 kV/cm for the 4.9 μm-emitting TA-type QCL.

FIG. 5 shows bar graphs of the components of the relative leakage-current density through the optical transition region energy states 5 and 6, for the 4.9 μm-emitting TA-type QCL. LO, and LO-only from g₄ stand for leakage triggered only by LO-phonon scattering in the presence of elastic scattering, and leakage only from the ul level, state g₄, in the absence of elastic scattering, respectively.

FIG. 6 plots voltage- and light-current curves of an 8.3 μm-emitting QCL vs. those obtained by using the inventors' modified NEGF modeling with graded interfaces. The employed graded-interface IFR-scattering parameters are: Δ=0.11 nm; Λ=6 nm; L=0.4 nm, and Λ_{⊥}=0.1 nm.

FIG. 7 shows the CB diagram and relevant wavefunctions for the 8.3 μm-emitting QCL at threshold. High energy state 4 is the upper laser level.

FIG. 8 shows bar graphs of the components of the relative leakage-current density through the optical transition region high energy states 5 and 6, for the 8.3 μm-emitting QCL. LO, and LO-only from high energy state 4 stand for leakage triggered only by LO-phonon scattering in the presence of elastic scattering, and leakage only from the high energy state 4 in the absence of elastic scattering, respectively.

FIG. 9 shows the CB diagram and relevant wavefunctions for an illustrative 8.1 μm-emitting STA-type QCL according to the present disclosure at threshold. State g₃ is the upper laser level.

FIG. 10 shows voltage- and light-current curves for the illustrative 8.1 μm-emitting STA-type QCL with photon-induced carrier transport, calculated using the inventors' modified NEGF modeling with graded interfaces. The employed graded-interface IFR-scattering parameters are: Δ=0.11 nm and 0.17 nm for all interfaces except those at the AlAs barrier, and for the interfaces bounding the AlAs barrier, respectively; Λ=6 nm; L=0.4 nm; and Λ_{⊥}=0.1 nm.

FIG. 11 shows bar graphs of the components of the relative leakage-current density, at threshold, through the optical transition region high energy states 5 and 6, for the illustrative 8.1 μm-emitting STA-type QCL. LO, and LO-only from state g₃ stand for leakage triggered only by LO-phonon scattering in the presence of clastic scattering, and leakage only from state g₃ in the absence of elastic scattering, respectively.

FIG. 12 shows wall-plug efficiency curves for the 8.3 μm-emitting QCL (WPE of 17%) and the illustrative 8.1 μm-emitting STA-type QCL (WPE of 22.2%). ηᵢ is the internal efficiency.

FIG. 13A shows a zoomed-in portion of a CB diagram and relevant wavefunctions (at lasing threshold Fₜₕ) for a mid-IR QCL configured to achieve interstage carrier injection. In this embodiment, an initial interstage carrier injection step involves carrier injection from a prior-stage injecting state directly into an upper laser level of the lasing stage, i.e., a direct carrier injection step. FIGS. 13B and 13C show zoomed-in portions of CB diagrams and relevant wavefunctions for the mid-IR QCL of FIG. 13A, but at higher F values including at the resonance point Fᵣₑₛ between state g₂ and the upper laser level 4 (ull) (FIG. 13B), and at the resonance point Fᵣₑₛ between state g₁ and state 4 (ull) (FIG. 13C). These figures demonstrate that the QCL is configured to achieve sequential direct carrier injection.

FIG. 14 shows a zoomed-in portion of a CB diagram and relevant wavefunctions (at Fₜₕ) for another mid-IR QCL also configured to achieve interstage carrier injection. In this embodiment, the prior-stage injecting state is the upper laser level of the lasing stage (from which lasing occurs) while the initial interstage carrier injection step involves carrier injection from the prior-stage injecting state into a high energy state 4 of the lasing stage. In this embodiment, the lasing (at Fₜₕ) may be characterized as occurring via carrier relaxation from the prior-stage injecting state that extends into the lasing stage. This feature enables strong PICT action. The QCL of FIG. 14 is configured to achieve sequential interstage carrier injection. The additional interstage carrier injection steps are via direct carrier injection.

FIG. 15 shows the schematic CB diagram and relevant wavefunctions for a QCL device that does not exhibit interstage carrier injection. Instead, carrier injection occurs within a stage (i.e., intrastage) from the ground state (g) of an injector region of the stage into the upper laser level of the stage through a single barrier.

FIG. 16 illustrates the mechanism of photon-induced carrier transport (PICT) in a QCL device for which injection from a prior-stage injecting state (inj) into an upper laser level (ull) of the lasing stage starts from threshold (Fₜₕ). FIG. 16 also shows a schematic of a voltage-current curve obtained from such a device.

FIG. 17 shows the CB diagram and relevant wavefunctions for an illustrative 4.7 μm-emitting STA-type QCL according to the present disclosure, at threshold (Fₜₕ).

FIG. 18 shows wall-plug efficiency curves for the 4.9 μm-emitting QCL (WPE of 27%) and the illustrative 4.7 μm-emitting STA-type QCL (WPE of 33%). ηᵢ is the internal efficiency.

### DETAILED DESCRIPTION

Quantum cascade lasers (QCLs) are provided that comprise a plurality of laser stages, each stage comprising alternating quantum well layers and barrier layers, wherein each stage is configured, upon application of an electric field F across all stages, to achieve interstage carrier (e.g., electron) injection and lasing, without carrier leakage. The applied electric field F may be a value at which lasing initially occurs, i.e., the lasing threshold Fₜₕ, but higher values may be used during operation of the QCL, as further described below.

Regarding interstage carrier injection, this refers to the mechanism by which carriers are injected from low energy states of a prior stage of the QCL into high energy states of a lasing stage of the QCL. For purposes of identifying the various stages within the QCL, the stage into which carriers are being injected is referred to as the “lasing stage” and the stage from which carriers are being injected is referred to as the prior stage, which is also an adjacent, upstream stage to the lasing stage. “Adjacent” means immediately next to, and “upstream” refers to a direction opposite to the flow of carriers through the QCL upon application of the electric field F (“downstream” refers to the same direction as the flow of carriers through the QCL). The terms “low” (and like like) and “high” (and the like) may be used in reference to the relative energy values of energy states or levels. The lowest energy state of any particular stage is referred to as a ground state g. These terms may refer to relative energy values in absence of the applied electric field F, since the relative energy values of a state can change as F changes.

Interstage carrier injection in the present QCLs involves injection of carriers from a low energy state of an adjacent, upstream stage into a high energy state of a lasing stage of the QCL. This low energy state of the adjacent, upstream stage from which carriers are injected may be referred to as an injecting state. However, this injecting state is not the lowest energy state existing in the adjacent, upstream stage, i.e., it is not a ground state. In addition, interstage carrier injection means that the carrier injection occurs via tunneling injection through multiple barriers that comprise barriers of the adjacent, upstream stage as well as barriers of the lasing stage. There may be at least 7 barriers involved in interstage carrier injection. This includes 7, 8, 9, or 10 barriers. The phrase “tunneling injection” encompasses resonant-tunneling injection well as incoherent tunneling injection that occurs due to scattering. The barriers of the adjacent, upstream stage involved in carrier injection include an exit barrier, which refers to the last barrier of the adjacent, upstream stage, and thus, defines the boundary between the adjacent, upstream stage and the lasing stage. Resonant-tunneling injection through these multiple barriers means that an injecting state wavefunction and the high energy state wavefunction are well overlapped over these multiple barriers, and thus, strongly couple, at and around their resonance point at a field Fᵣₑₛ for the QCL. Resonant-tunneling injection is further described below.

In embodiments, interstage carrier injection involves injection of carriers from the injecting state of the adjacent, upstream stage into the upper laser level of the lasing stage of the QCL, where they relax to a lower laser level of the lasing stage with an emission of a photon. Since the present lasers are quantum cascade lasers, this transition between the upper laser level and the lower laser level is an intraband (i.e., not an interband) transition. In these embodiments, the high energy state of the lasing stage is the upper laser level and so the carriers from the prior stage are injected directly into the upper laser level of the lasing stage. Thus, this type of interstage carrier injection may be referred to as “direct carrier injection.”

In other embodiments, interstage carrier injection involves injection of carriers from the injecting state of the adjacent, upstream stage into a high energy state of the lasing stage, but one that is not the upper laser level of the lasing stage of the QCL. This occurs in embodiments in which the injecting state of the adjacent, upstream stage is itself the upper laser level of the lasing stage from which carriers undergo an intraband transition and emit a photon.

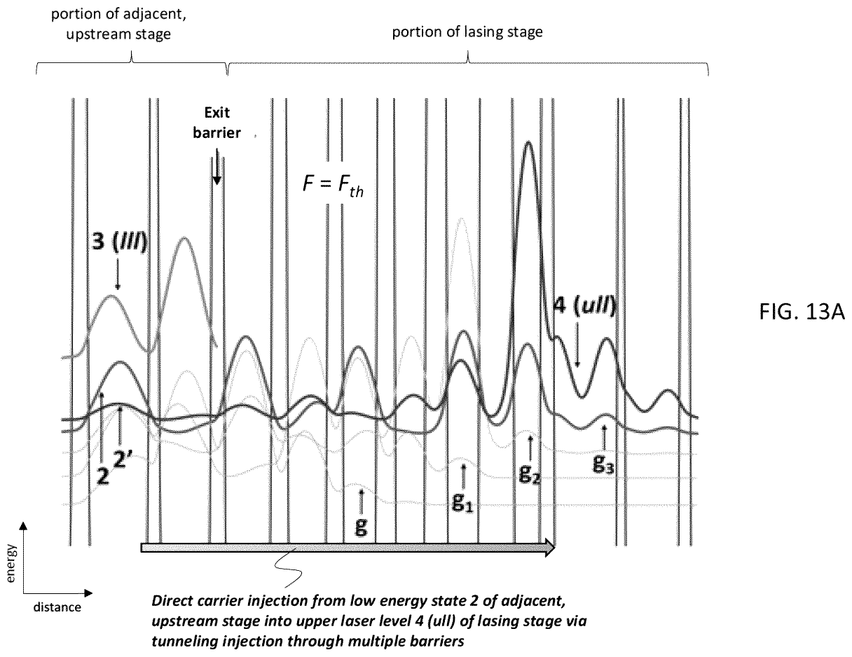

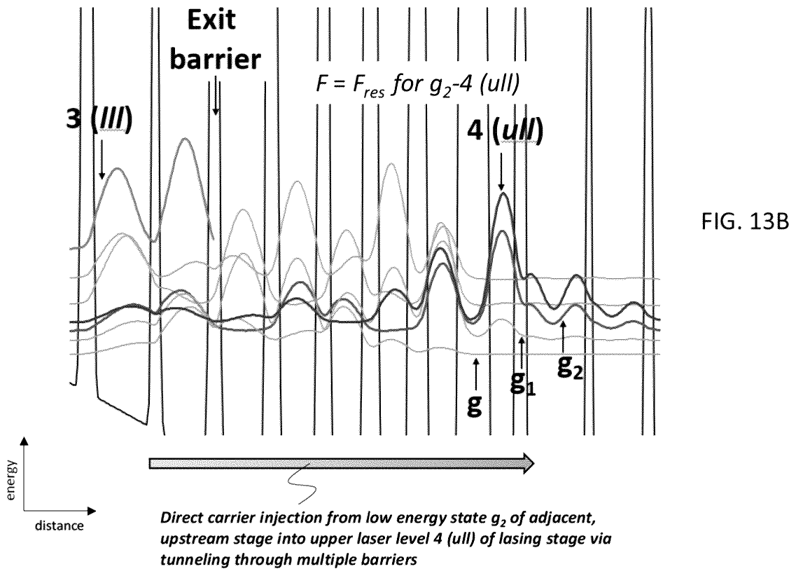

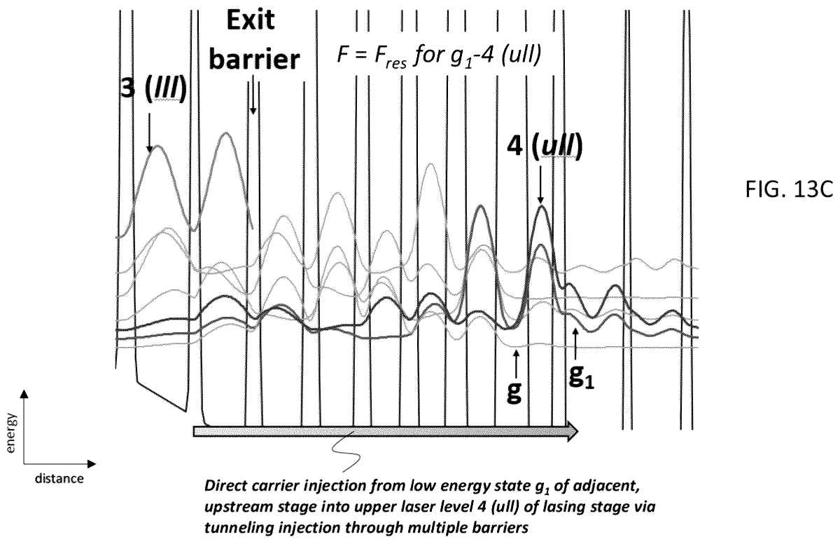

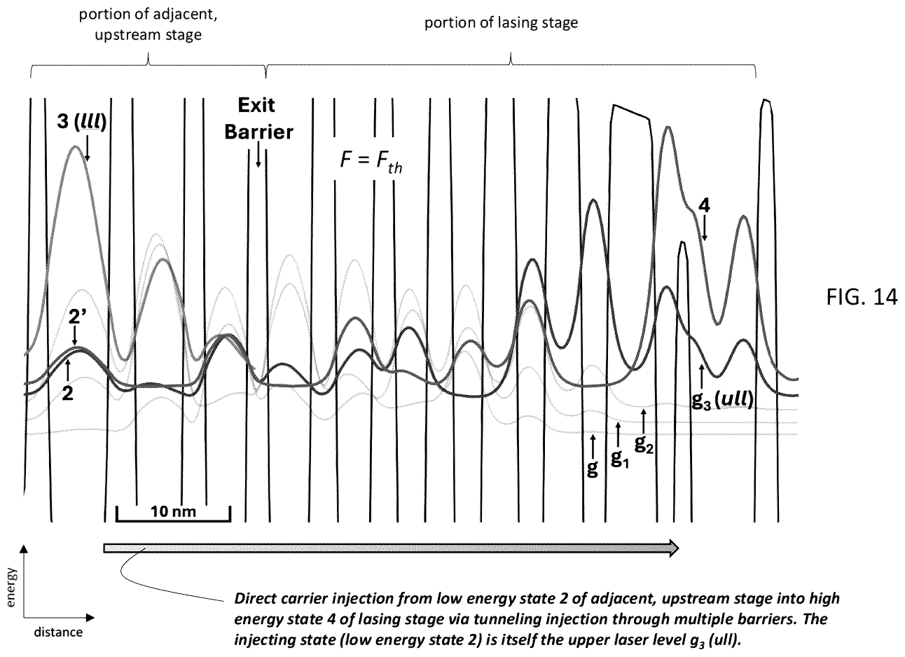

The present QCLs are generally configured to achieve multiple interstage carrier injection steps as F increases from Fₜₕ to QCL shutoff. This includes a first, or initial, interstage carrier injection step (e.g., at Fₜₕ) and one or more additional interstage carrier injection steps as F increases beyond Fₜₕ. This feature of the present QCLs may be referred to as “sequential interstage carrier injection.” In embodiments, all interstage carrier injection steps are direct carrier injection steps. Such embodiments are further described below with reference to FIGS. 13A-13C. In other embodiments, the initial interstage carrier injection step is not a direct carrier injection step, but one or more of the additional interstage carrier injection steps are direct carrier injection steps. Such embodiments are further described below with reference to FIG. 14.

Further regarding sequential direct carrier injection, the injection is sequential in that it involves sequential injection into the upper laser level of the lasing stage from prior-stage low energy states. After an initial injecting state reaches its resonance point with the upper laser level, a next low energy state injects into the upper laser level up to its respective resonance point with the upper laser level. The process repeats itself until a final injecting state reaches its respective resonance point with the upper laser level, when lasing ceases at QCL shutoff.

In view of the nature of the mechanism of interstage carrier injection involving multiple barriers and lasing as further described below, in the present QCLs, the entire lasing stage, i.e., the whole stage, may be considered to be an optical transition region.

The mechanism of interstage carrier injection is illustrated by reference to an embodiment shown in FIG. 13A, which shows a zoomed-in portion of the conduction band diagram and relevant wavefunctions for a QCL configured to achieve interstage carrier injection. The conduction band diagram and relevant wavefunctions are shown at the lasing-threshold field Fₜₕ for the QCL. The adjacent, upstream stage includes a lower laser level (i.e., state) 3 (lll). The exit barrier layer corresponds to the last barrier layer of the adjacent, upstream stage and thus, defines the boundary between stages. The adjacent, upstream stage also includes a first low energy state 2 and a second low energy state 2′ which are both lower in energy than the lower laser level 3 (lll) (hence, energy states 2 and 2′ are referred to as low energy states). However, the first and second low energy states 2 and 2′ are not the lowest energy states of the adjacent, upstream stage; i.e., they are not the ground state g (also shown in FIG. 13A). The lasing stage includes an upper laser level (i.e., state) 4 (ull). Other states existing in the QCL are labeled as g, g₁, g₂ and g₃. Importantly, the two low energy states 2 and 2′ of the adjacent, upstream stage correspond to certain energy states in the lasing stage as evidenced by the corresponding states having identical sheet-carrier density and carrier temperature to each other. Specifically, the first low energy state 2 corresponds to the state g₃ and the second low energy state 2′ corresponds to the upper laser level 4 (ull). Thus, carrier injection occurs from the first low energy state 2 of the adjacent, upstream stage into the upper laser level 4 (ull) of the lasing stage, via tunneling injection, through multiple barriers (˜8) over a relatively wide (˜50 nm) region of the QCL.

As noted above, and also shown in FIG. 13A via the horizontal arrow, the multiple barriers through which tunneling injection occurs comprise barriers in the adjacent, upstream stage (including the exit barrier of the adjacent, upstream stage) as well as barriers in the lasing stage. As shown in FIG. 13A, the injecting state wavefunction (i.e., the wavefunction for the first low energy state 2) and the upper laser level wavefunction (i.e., the wavefunction for the upper laser level 4 (ull)) both penetrate through these multiple barriers due to electron resonant tunneling. Over this region, the two wavefunctions are well overlapped, and thus, strongly couple, at a resonance point at an applied electric field Fᵣₑₛ, that is higher than the lasing threshold, Fₜₕ. Resonant-tunneling injection occurs through the multiple barriers due to coupling between the two wavefunctions. For this QCL, Fₜₕ is 43.2 kV/cm and, at this value, the two wavefunctions already are well overlapped and strongly couple. However, the resonance point characterizing the coupling between the wavefunctions for state 2/g₃ and state 4 (ull) is at a higher field value Fᵣₑₛ of 45.5 kV/cm. Thus, Fᵣₑₛ is about 5% higher than Fₜₕ. In general, the resonance point Fᵣₑₛ characterizing the coupling between these two wavefunctions may be no more than 6% above Fₜₕ. no more than 5% above Fₜₕ, no more than 4%, no more than 3%, no more than 2% above Fₜₕ, no more than 1% above Fₜₕ, or a range of between any of these values.

The interstage carrier injection described above with respect to FIG. 13A is an initial, direct carrier injection step. FIGS. 13B and 13C illustrate additional direct carrier injection steps that occur at higher values of F. Specifically, as shown in FIG. 13B, above Fᵣₑₛ for 2/g₃−4 (ull), direct carrier injection continues into state 4 (ull), from state g₂ up to the g₂−4 (ull) resonance point Fᵣₑₛ at 53.5 kV/cm. Next, as shown in FIG. 13C, direct carrier injection continues into state 4 (ull), from state g₁ up to the g₁−4 (ull) resonance point at 59.5 kV/cm, after which point the QCL shuts off.

The QCL shown in FIGS. 13A-13C and described above may be characterized as one configured to achieve sequential interstage carrier injection, more specifically, sequential direct carrier injection since the initial interstage carrier injection step is a direct carrier injection step and each additional interstage carrier injection step is also a direct carrier injection step.

The mechanism of interstage carrier injection is further illustrated by reference to an embodiment shown in FIG. 14, which shows a zoomed-in portion of the conduction band diagram and relevant wavefunctions for a different QCL, but also configured to achieve interstage carrier injection. At threshold Fₜₕ, there is interstage carrier injection from the low energy state 2 (corresponding to state g₃) into high energy state 4 (corresponding to low energy state 2′). Neither low energy state 2 nor 2′ is the ground state g (also shown in FIG. 14). However, in this embodiment lasing is favored from state g₃ rather than from high energy state 4 because of a larger differential gain coefficient for state g₃. That is, state g₃ is the upper laser level (ull) of the lasing stage. Thus, the prior-stage injecting state (low energy state 2) is itself ull. Again, in this embodiment, carrier injection occurs via tunneling injection through multiple barriers (˜8) over a relatively wide (˜50 nm) region of the QCL.

As noted above, and also shown in FIG. 14 via the horizontal arrow, the multiple barriers through which tunneling injection occurs comprise barriers in the adjacent, upstream stage (including the exit barrier of the adjacent, upstream stage) as well as barriers in the lasing stage. Resonant-tunneling injection through these multiple barriers means that the injecting state wavefunction (i.e., the wavefunction for the low energy state 2) and the high energy state 4 wavefunction strongly couple to each other. For this QCL, Fₜₕ is 65 kV/cm and the resonance point between state 2/g₃ (ull) and high energy state 4 occurs at Fᵣₑₛ=68 kV/cm. Thus, Fᵣₑₛ is about 5% higher than Fₜₕ. In general, the resonance point Fᵣₑₛ characterizing the coupling between these two wavefunctions may be no more than 6% above Fₜₕ. no more than 5% above Fₜₕ, no more than 4%, no more than 3%, no more than 2% above Fₜₕ, no more than 1% above Fₜₕ, or a range of between any of these values.

The interstage carrier injection described above with respect to FIG. 14 is an initial interstage carrier injection step. This step is not a direct carrier injection step. Rather, because the injecting state of the initial interstage carrier injection step is itself the ull, lasing (at Fₜₕ) may be characterized as occurring via carrier relaxation from a prior-stage energy state that extends into the lasing stage. As further described below, this feature has the unique advantage of increasing the strength of PICT action in a QCL device. Similar to the embodiments of FIGS. 13B and 13C, the embodiment of FIG. 14 also allows for additional interstage carrier injection steps, specifically, direct carrier injection steps, that occur at higher values of F, followed by lasing. Specifically, above Fᵣₑₛ for 2/g₃−4, high energy state 4 becomes the upper laser level and direct carrier injection occurs into 4 (ull) from state g₂ up to the g₂−4 (ull) resonance point Fᵣₑₛ at 72 kV/cm. Next, direct carrier injection continues into state 4 (ull), from state g₁ up to the g₁−4 (ull) resonance point at 80 kV/cm, after which point the QCL shuts off.

The QCL shown in FIG. 14 and described above may be characterized as one configured to achieve sequential interstage carrier injection. In this embodiment, the initial interstage carrier injection step is not a direct carrier injection step, but each additional interstage carrier injection step is a direct carrier injection step.

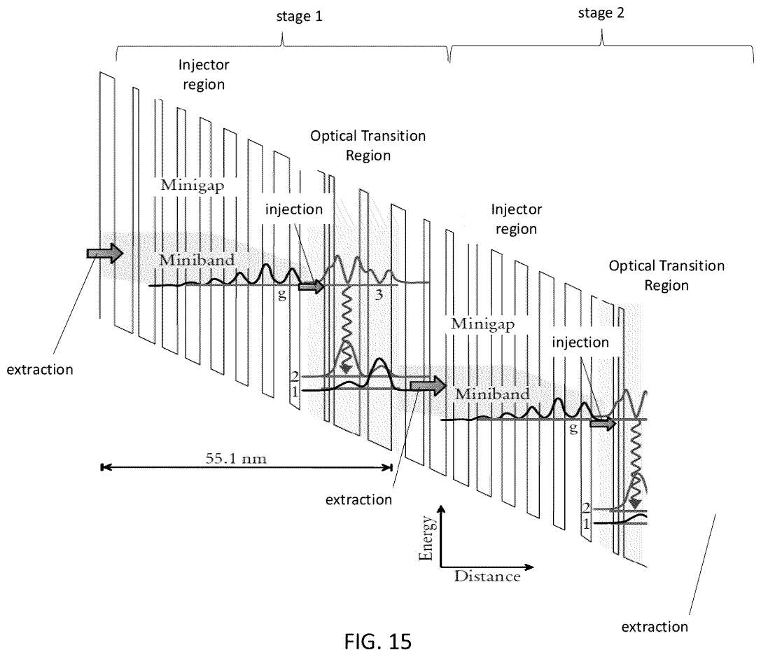

Direct carrier injection is distinguished from the mechanism of carrier injection in existing QCLs which is part of a carrier transport process that occurs only within the lasing stage and thus, is an intrastage process. In addition, unlike the present QCLs, in these existing QCLs, resonant-tunneling injection occurs through a single barrier. This intrastage process is illustrated by reference to FIG. 15, which shows the conduction band diagram and relevant wavefunctions for two stages of a QCL configured to achieve intrastage carrier injection. In this mechanism, and moving from left to right, carriers are extracted through the exit barrier layer of an adjacent, upstream stage; tunnel through barrier layers of an injector region of a lasing stage (stage 1) as they scatter down, losing energy, to a ground state g of the injector region of the lasing stage; and are injected into an upper laser level 3 of an optical transition region of the lasing stage via resonant tunneling through a single injection barrier (not multiple barriers) of the optical transition region of the lasing stage.

By contrast to the description above for FIGS. 13A-13C and 14, which applies to the present QCLs, in FIG. 15, the injecting state wavefunction (the wavefunction for the ground state g) and the upper laser level wavefunction (the wavefunction for the upper laser level 3) only partially penetrate a single barrier (the injection barrier). In addition, the resonance point characterizing the coupling between the two wavefunctions occurs at laser shutoff. For the QCLs described in FIGS. 13A-C and 14, QCL shutoff occurs at the resonance point between the upper laser level and an injecting state that is different from the injecting state at lasing threshold (i.e., the initial injecting state). For example, in FIG. 13C, QCL shutoff occurs at the resonance point of the injecting state g₁ with the upper laser level, while the initial injecting state was 2/g₃.

In addition to the QCL configuration shown in FIG. 15, it is noted that the QCL configurations described in U.S. Pat. Nos. 8,325,774 and 8,848,754 also are not configured to achieve interstage carrier injection, but rather intrastage carrier injection as shown in FIG. 15.

Regarding the configuration of the stages of the present QCLs, this refers to physical characteristics of each stage, including the number of quantum well layers and barrier layers; the composition of individual quantum well layers/barrier layers; the doping state (doped or undoped) as well as doping level of individual quantum well layers/barrier layers; the arrangement of individual quantum well layers/barrier layers; and the thicknesses of individual quantum well layers/barrier layers. These physical characteristics, in turn, determine the characteristics of the conduction band of each stage and thus, its wavefunctions. These wavefunctions, in turn, determine the carrier injection and lasing mechanisms for each stage. As noted above, the physical characteristics of the stages of the present QCLs are selected, i.e., configured, such that they achieve interstage carrier injection, including all of the variations thereof described above (e.g., direct carrier injection). Confirmation that a selected configuration achieves interstage carrier injection may be carried out by using the inventors' modified NEGF-based, IFR scattering formalism as described in detail in the Examples, below, so as to obtain the conduction band diagram and relevant wavefunctions for the selected configuration.

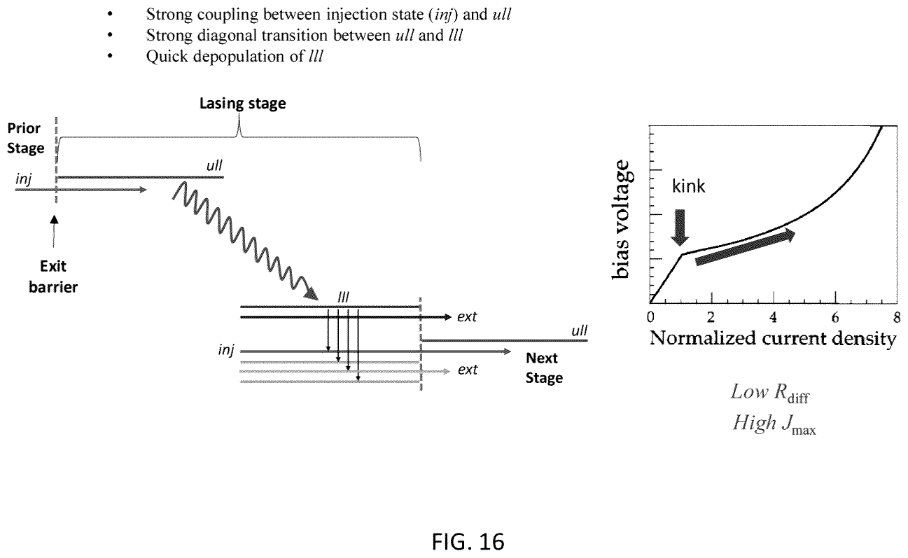

In addition to interstage carrier injection, the stages of the present QCLs may further be configured to exhibit photon-induced carrier transport (PICT). This refers to the carrier transport through the QCL being induced by emitted photons, rather than the applied electrical field F. That is, the current through the QCL is a photocurrent. PICT action is illustrated by reference to FIG. 16 for a QCL configured accordingly. The injection state (inj), the upper laser level ull, and the lower laser level Ill are labeled; extraction is labeled as “ext”. This figure also makes clear that the entire lasing stage, i.e., the whole stage, is an optical transition region. PICT action, including the strength of the PICT action, depends upon three factors, described immediately below.

First, PICT action is strengthened by strong coupling between the energy state from which injection (inj) occurs and the upper laser level ull of the lasing stage. By strong coupling it is meant that the splitting energy at resonance between these two energy states is relatively high, e.g., at least 5 meV. This includes at least 6 meV, at least 7 eV, at least 8 cV, at least 9 cV, at least 10 eV, or a range in between any of these values, e.g., from 5 meV to 8 me V.

Second, PICT action requires a strong diagonal transition between the upper laser level ull of the lasing stage and a lower laser level lll of the lasing stage. By strong diagonal transition, it is meant that the dipole matrix element for ull and lll, i.e., z_{ul,ll}, is relatively small, e.g., less than 10 Å. This includes less than 9 Å, less than 8 Å, less than 7 Å, less than 6 Å, less than 5 Å or a range in between any these values, including from 6 Å to 8 Å. If there are lasing transitions to multiple lower laser levels, their corresponding dipole-matrix-element values are combined to give an overall dipole matrix element.

Third, PICT action requires quick gain recovery, which means quick depopulation of the lower laser level lll of the prior stage followed by injection via tunneling injection into the ull of the lasing stage. By quick depopulation, it is meant that the lifetime of the lower laser level, i.e., τₗₗ, is relatively short, e.g., no more than 0.15 ps. This includes no more than 0.12 ps, no more than 0.09 ps, no more than 0.06 ps, or in a range in between any of these values, including from 0.05 ps to 0.10 ps. If there are transitions from multiple lower laser levels and/or multiple relaxation pathways from a lower laser level, the overall lower-laser-level lifetime is referred to as global lower-laser-level (lll) lifetime, i.e., τ_{ll,g}. Tunneling time into the ull is on the order of ˜0.5 ps. However, for QCLs for which a prior-stage low energy state is the ull of the lasing stage (i.e., the QCL of FIG. 14), gain recovery is much faster since the only time delay is the Ill lifetime. This advantageously results in even stronger PICT action.

Like interstage carrier injection, the configuration of the stages of the present QCLs determines its conduction band characteristics and wavefunctions, which determines the nature of the carrier transport through the QCL. Thus, the stages of the present QCLs may be configured to ensure PICT action. This includes configurations that exhibit the values of the PICT factors described above. Confirmation that a selected configuration exhibits PICT action may be carried out by using the inventors' modified NEGF-based, IFR scattering formalism as described in the Examples, below, so as to obtain the conduction band diagram and relevant wavefunctions for the selected configuration. From these, the PICT factors may be calculated for the selected configuration.

Finally, it is noted that PICT action is also evidenced by QCL voltage-current (V-I) curves having certain characteristics, including a strong kink in the V-I curve at Fₜₕ. This is illustrated in the V-I curve shown in FIG. 16. In addition, as illustrated in the Examples, below, PICT action QCLs exhibit relatively low differential resistance R_{diff} values (e.g., about 40 to 50% less) and relatively high maximum current density values, Jₘₐₓ (e.g., 1.5 times greater) and as compared to comparative non-PICT action QCLs emitting at about the same wavelength. V-I curves, R_{diff} values, and Jₘₐₓ values may be calculated using the inventors' modified NEGF-based, IFR scattering formalism as described in the Examples, below, or experimentally determined as is known. This may be done to further confirm PICT action for a selected stage configuration.

As noted above, the stages of the present QCLs are also configured such that the lasing described above occurs without carrier leakage. In the present disclosure, carrier leakage refers to normalized leakage-current density Jₗₑₐₖ/J, wherein Jₗₑₐₖ is the leakage-current density and J is the current density. The term “without” with respect to carrier leakage encompasses, but does not require, total suppression of the carrier leakage in the present QCLs. The term “without” encompasses the present QCLs exhibiting Jₗₑₐₖ/J values of no more than 20%, no more than 15%, no more than 10%, no more than 5%, and ranges of between any of these values, e.g., from 5% to 7% and from 4% to 10%. These values may refer to Jₗₑₐₖ/J at the lasing-threshold field Fₜₕ of the QCL. The Jₗₑₐₖ/J values for a particular QCL device may be calculated using the inventors' modified carrier-leakage formalism as described in the Example, below.

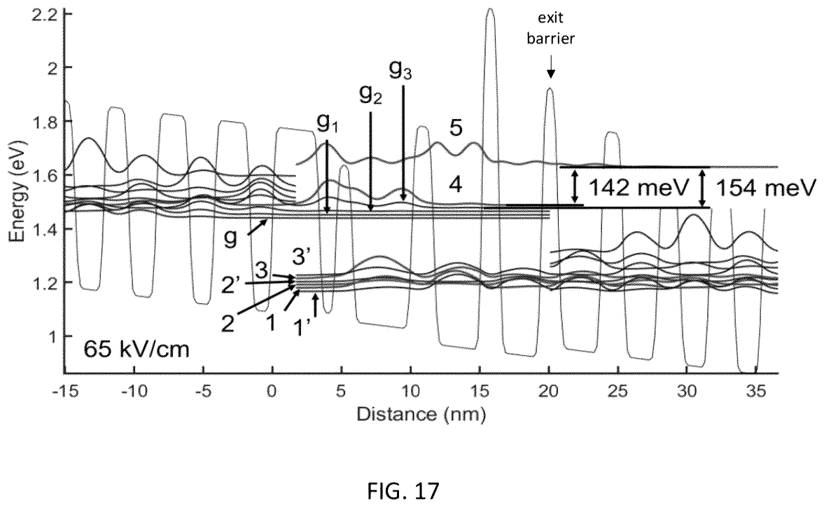

Conduction band engineering as described above with respect to direct carrier injection and PICT action may be used to achieve reductions in Jₗₑₐₖ/J, including by adjusting (e.g., increasing) the difference between the energy values of the energy states involved in relevant carrier leakage pathways. For example, by reference to FIG. 17, carrier leakage occurring from the upper laser level g₃ to the high energy state 5 as well as from the high energy state 4 to the high energy state 5 is greatly suppressed due to the very large energy differences designed into this QCL device: E_{5g3}=154 meV and E₅₄=142 meV.

However, additional reductions in in Jₗₑₐₖ/J may be achieved based on the inventors' discovery that relatively low values of an interface overlap factor (IOF) contribute to suppressing carrier leakage. The IOF refers to the degree of overlap between the relevant wavefunctions (e.g., between the upper laser level g₃ and an adjacent high energy state, i.e., the high energy state 5) at relevant interfaces. For a particular stage configuration, IOF values may be calculated as described in the Examples below (see Equation S1b) and adjustments to the configuration may be made as desired. IOF values of no more than 3×10⁻⁵, no more than 5×10⁻⁵, no more than 7×10⁻⁵, no more than 10⁻⁴, or a range of between any of these values, including from 3×10⁻⁵ to 10⁻⁴.

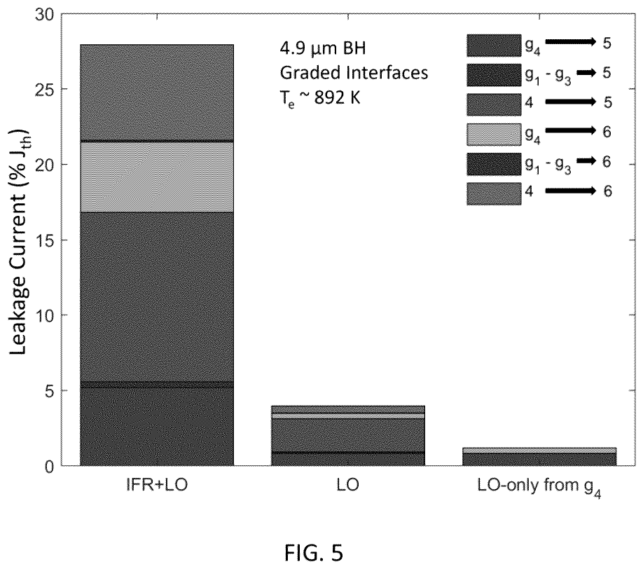

Finally, as shown in FIGS. 5, 8, and 11, the primary component of carrier leakage has been found to be interface roughness (IFR)-triggered carrier leakage

$${J}_{l e a k}^{IFR} .$$

As also described in the Examples, below, even further reductions in Jₗₑₐₖ/J may be achieved based on the inventors' discoveries as to how certain IFR parameters of the QCL may be adjusted to reduce

$${J}_{l e a k}^{IFR}$$

and thus, Jₗₑₐₖ/J. The Irk parameters, which describe the physical characteristics of interfaces formed between quantum well layers and barrier layers in the stages of the present QCLs include: root-mean square (RMS) height Δ; in-plane correlation length Λ; graded-interface width L; and axial correlation length Λ_{⊥}.

Regarding the IFR parameters, the inventors have found that increasing L/Λ_{⊥} ratios reduce Jₗₑₐₖ/J. This means that using wider graded interfaces leads to larger reductions in

$${J}_{l e a k}^{IFR} .$$

This is a counterintuitive result. L/Λ_{⊥} values of at least 2 may be used. This includes at least 3, at least 4, or a range of between any of these values, including from 3 to 7. The inventors have found that smaller Δ values reduce carrier leakage since

$${J}_{l e a k}^{IFR}$$

is proportional to Δ². Δ values of no more than 0.10 nm may be used. This includes no more than 0.14 nm, no more than 0.16 nm, no more than 0.18 nm, no more than 0.20 nm, or a range of between any of these values, including from 0.10 nm to 0.20 nm. noted below, crystal growth conditions used to fabricate the quantum well layers and the barrier layers of the stages of the present QCLs may be selected to achieve desired IFR values. The graded-interfaces IFR parameters may be measured using atom probe tomography.

As discussed above, conduction band engineering, IFR engineering, and optimization of crystal growth conditions are used (in conjunction with the inventor's modified NEGF-based, IFR analysis and carrier-leakage formalism) to arrive at a variety of stage configurations can achieve interstage carrier injection and PICT action without carrier leakage. Additional guidance for selecting stage configurations is further provided below. Regarding composition, as illustrated in FIG. 17, the quantum well layers and barrier layers of the present QCLs do not have the same, fixed alloy compositions (by contrast to those in the QCL of FIG. 15). Otherwise, various semiconductors, e.g., III-V semiconductors, may be used for the quantum well layers and barrier layers of the present QCLs. Binary, ternary, quaternary III-V semiconductor alloy compositions may be used in which various relative amounts of each III element and each V element may be used. Illustrative III-V semiconductor alloys include, e.g., GaAs, AlAs, InGaAs, AlInAs, AlAsSb, AlGaAs, GaAsP, AlGaAsP.

The quantum well layers in the stages of the present QCLs may include those having different energy values as compared to other quantum well layers in the stages, i.e., all quantum well layers need not have the energy value. Similarly, the barrier layers in the stages of the present QCLs may include those having different energy values as compared to other quantum well layers in the stages, i.e., all barrier layers need not have the same energy value. The energy of a quantum well layer may be defined as the difference in energy between the well bottom of the quantum well layer and the top of the adjacent, upstream barrier layer. The energy of a barrier layer may be defined as the difference in energy between the top of the barrier layer and the well bottom of the adjacent, upstream quantum well layer. Energies are determined from unbiased structures. For graded (versus abrupt) quantum well layers and barrier layers, such as those shown in FIG. 17, the energies of “well bottoms” and “tops” are taken from the flat regions thereof (versus the graded sides). Stages may be used that include a series (e.g., 2, 3, 4 or more) of adjacent quantum well layers and/or adjacent barrier layers that increase in energy or decrease in energy in a particular direction (i.e., upstream or downstream) and in a particular way (e.g., linearly, step-wise). As noted above, different doping states, doping levels, and/or thicknesses may be used for individual quantum well layers/barrier layers.

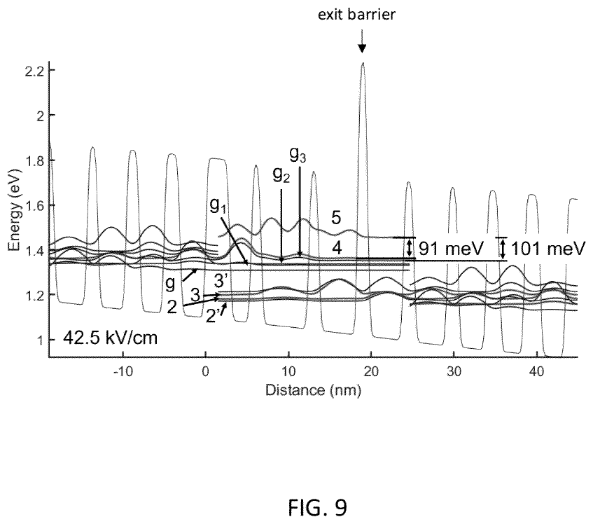

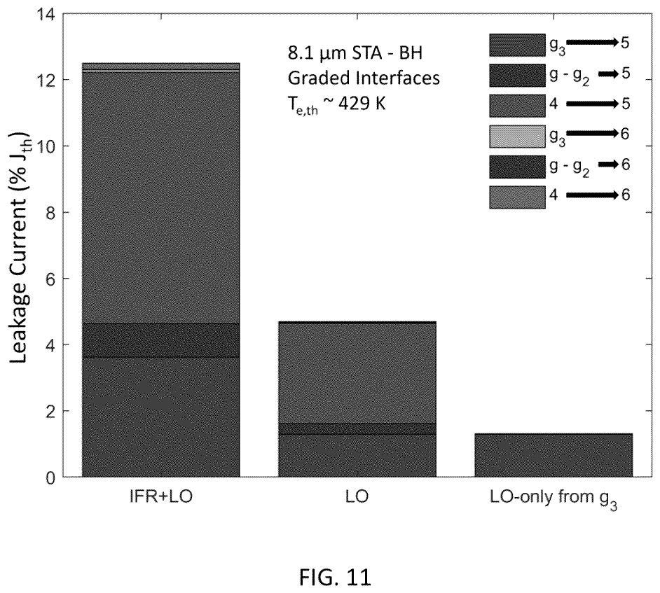

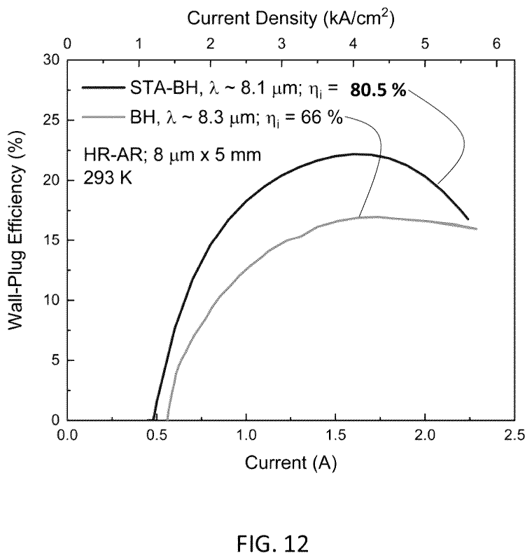

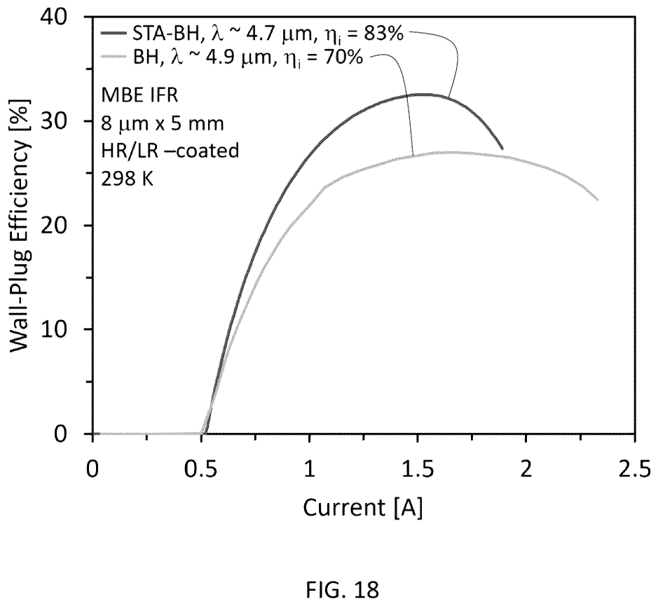

As described in more detail in Example 1, the conduction band diagram and relevant wavefunctions for an illustrative QCL (8.1 μm) according to the present disclosure is shown in FIG. 9; its carrier leakage is shown in FIG. 11; and its room-temperature WPE-I curve is shown in FIG. 12. As described in more detail in Example 2, the conduction band diagram and relevant wavefunctions for an illustrative QCL (4.7 μm) according to the present disclosure is shown in FIG. 17; and its room-temperature WPE-I curve is shown in FIG. 18.

The present QCLs may be grown on an appropriate substrate using metal-organic chemical vapor deposition (MOCVD) or molecular beam epitaxy (MBE). Crystal growth conditions may be adjusted to achieve certain IFR parameters and reduce carrier leakage. In addition, crystal growth conditions may be adjusted to reduce the waveguide loss α_{w}.

As noted above, the present QCLs comprise a plurality of stages. This includes, e.g., at least 10, at least 25, at least 30, or at least 40 stages. Each stage may be configured as described herein. The QCLs may further comprise other known components, e.g. waveguide layer(s), substrate, and contact layer(s). The laser light emitted from the present QCLs is generally in infrared range, which includes the mid- to long-wavelength infrared range (i.e., 3-20 μm). This includes QCLs configured to emit laser light in the wavelength range from 4 μm to 6 μm, from 4 μm to 5 μm, from 7 μm to 12 μm, and from 8 μm to 9 μm.

As noted above, the inventors' approach described herein, for the first time, enables QCLs exhibiting wall-plug efficiencies (WPE) near their theoretical limits. In embodiments, the QCL is configured to emit 4 μm to 6 μm laser light with a WPE at room temperature that is at least 30%, at least 32%, at least 35%, or at least 37%. This includes a range of between any of these values, e.g., 30% to 40%. In embodiments, the QCL is configured to emit 7 μm to 10 μm laser light with a WPE at room temperature that is at least 20%, at least 22%, or at least 24%. This includes a range of between any of these values, e.g., 20% to 25%. The present QCLs may be operated at other temperatures, e.g., under thermoelectric cooling conditions (about 240 K) or under cryogenic conditions (about 40 K), in which case the WPE values will increase as operating temperatures decrease. The operating temperature may be any of these values or greater than 250 K, greater than 275 K, greater than 290 K, or a range in between any of these values, e.g., from 250 K to 298 K.

The present disclosure encompasses the QCLs as well as methods of using the QCLs to emit laser light, e.g., by applying the electric field F, including Fₜₕ.

In embodiments, the QCL comprises a plurality of stages, each stage comprising alternating quantum well layers and barrier layers, wherein each stage is configured, upon application of an electric field F across the plurality of stages, to inject carriers from a low energy state of an adjacent, upstream stage of the plurality of stages into a high energy state of a lasing stage of the plurality of stages, via tunneling injection through multiple barrier layers comprising barrier layers of the adjacent, upstream stage and barrier layers of the lasing stage, wherein carriers in the lasing stage undergo intraband transitions from an upper laser level of the lasing stage to at least one (e.g., 2) lower laser level of the lasing stage with the emission of laser light and without carrier leakage.

In embodiments, the QCL comprises a plurality of stages, each stage comprising alternating quantum well layers and barrier layers, wherein each stage is configured, upon application of an electric field F across the plurality of stages, to inject carriers from a low energy state of an adjacent, upstream stage of the plurality of stages into a high energy state of a lasing stage of the plurality of stages, via tunneling injection through multiple barrier layers comprising barrier layers of the adjacent, upstream stage and barrier layers of the lasing stage, wherein carriers in the lasing stage undergo intraband transitions from an upper laser level of the lasing stage to at least one (e.g., 2) lower laser level of the lasing stage with the emission of laser light, and further wherein, the low energy state is the upper laser level.

The present QCLs may be understood more readily by reference to the following examples, which are provided by way of illustration and are not intended to be limiting.

### EXAMPLES

### Example 1

### Introduction

This Example describes the inventors' modification of the nonequilibrium Green's functions (NEGF)-based, interface-roughness (IFR) scattering formalism of T. Grange, et al., Phys. Rev. Applied, vol. 13, no 4, 044062, 2020. The modified NEGF-based analysis was used to reveal key device-design features for achieving high-performance IR QCLs at room temperature. These features include injection from a prior-stage low energy state of the optical transition region directly into the upper laser (ul) level of the optical transition region of a given stage (i.e., direct carrier injection); photon-induced carrier transport (i.e., PICT action); and suppressed carrier leakage (i.e., minimized Jₗₑₐₖ/J). These findings, along with conduction band engineering, IFR scattering engineering, and optimized crystal growth conditions, are then leveraged to arrive at new QCLs exhibiting superior performance, including WPE values much closer to the theoretical limit.

High Front-Facet Wall-Plug Efficiency 4.9 μm-Emitting QCL

The device (Bai, Y., et al.) examined is of the so-called shallow-well design which was shown to be of the (linear)-tapered (TA) type, in that optical transition region barrier heights increase linearly from the conventional-injection barrier to the exit barrier. The front-facet maximum pulsed WPE value is 27%, at 298 K heatsink temperature.

### Modified NEGF-Based Analysis

As mentioned above, the NEGF formalism for modeling with graded interfaces was modified for use in mid-IR QCL analysis, as discussed below. Specifically, the model was extended to k·p multiband theory, and modified to take into account the variation of the effective mass in the graded regions, as well as the Δ values for each graded interface. The inputs to the model for a given QCL structure were: the layer compositions and nominal thicknesses for one stage; the injector sheet-doping density; the sum of the waveguide loss, α_{w}, and mirror loss, αₘ; the optical-mode confinement factor to the core region, Γ; and the values for the four IFR parameters: root-mean square (RMS) height Δ; in-plane correlation length Λ; graded-interface width L; and axial correlation length Λ_{⊥}. Using the experimentally measured 6 nm value for Λ and 0.135 nm value for Δ of moderately strained barriers, the other two IFR parameters were deduced by matching the Jₜₕ value and the V-I curve, while taking into consideration that Δ increases with the barriers' Al content. Then what is obtained is Δ=0.10 nm at the lattice-matched barrier interfaces, 0.13 nm at the moderately strained barriers' interfaces, and 0.17 nm at the heavily strained AlAs barriers' interfaces; L=0.4 nm; and Λ_{⊥}=0.1 nm. The different Δ values are consistent with the trend found from APT-data analysis, that Δ increases with the layer's relative strain with respect to the InP substrate, and the fact that AlAs layers may have residual oxygen incorporation. In particular, the A value at the moderately strained barriers' interfaces (i.e., 0.13 nm) is similar to that found via APT (i.e., ˜0.135 nm) for almost identical barriers (i.e., Al_{0.64}In_{0.36}As vs. Al_{0.65}In_{0.35}As), while the value at the AlAs barriers' interfaces (i.e., 0.17 nm) is smaller than that found via APT (i.e., 0.2 nm), most likely due to the crystal growth method used [i.e., gas-source molecular beam epitaxy (GS-MBE)] which should have less residual oxygen incorporation than MOCVD, given to ultrahigh-vacuum chambers employed in MBE-growth reactors.

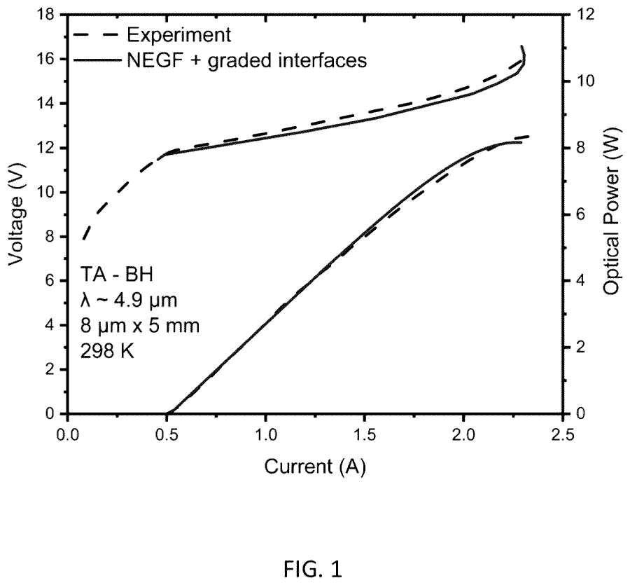

The experimental V-I and L-I curves were compared to those generated via the modified NEGF model with graded interfaces in FIG. 1. The differential resistance R_{diff} has a 1.6Ω calculated value, quite close to the 1.7Ω experimental value, and the maximum current density, Jₘₐₓ, is basically the same in both cases: 5.76 kA/cm² vs. ˜5.75 kA/cm². The L-I curve is well approximated to the maximum peak pulsed front-facet emitted power of ˜8 W. To the best of the inventors' knowledge, this is the first time that the electro-optical characteristics of this QCL have been theoretically reproduced.

It was noted that the R_{diff} value was ˜50% of the value obtained for a conventional, 40-stage 4.8 μm-emitting QCLs (i.e., 3.5Ω) of same buried-ridge dimensions (i.e., ˜8 μm×5 mm). (M. Razeghi, Proc. SPIE, vol. 7230, 723011, 2009.) Furthermore, subtracting the calculated cladding resistance value of ˜0.5Ω, the core-region R_{diff} value is ˜40% that for the conventional QCL (i.e., 1.2Ω vs. 3Ω). The difference can only be explained by the fact that above threshold there is significant PICT action; that is, virtually all carrier transport is photon induced. The onset of PICT action is evidenced by the sharp ‘kink’ in the V-I curve at threshold. The other telltale sign of PICT action is that, for the same injector sheet-doping density, nₛ (i.e., 0.9×10¹¹ cm²), the Jₘₐₓ value is ˜1.5 times the value for conventional QCLs (i.e., 3.8 kA/cm²). This is evidence of PICT-action QCLs which have significantly shorter transit time τₜᵣₐₙₛ than conventional QCLs, since carrier transport in a PICT-action QCL is in large part limited by the photon-assisted tunneling time between the upper-laser (ul) and lower-laser (ll) levels, while for a conventional QCL τₜᵣₐₙₛ involves the electrically driven average transport time through one stage. For this device, since

$${J}_{max} = \frac{{en}_{s}}{{τ}_{trans}} ,$$

the τₜᵣₐₙₛ value at shutoff decreases from ˜3.8 ps for conventional 4.9 μm-emitting QCLs to ˜2.5 ps. Therefore, for this PICT-action device, the combination of lower voltage values above threshold and increased dynamic range causes the maximum WPE value to become significantly higher than for conventional QCLs.

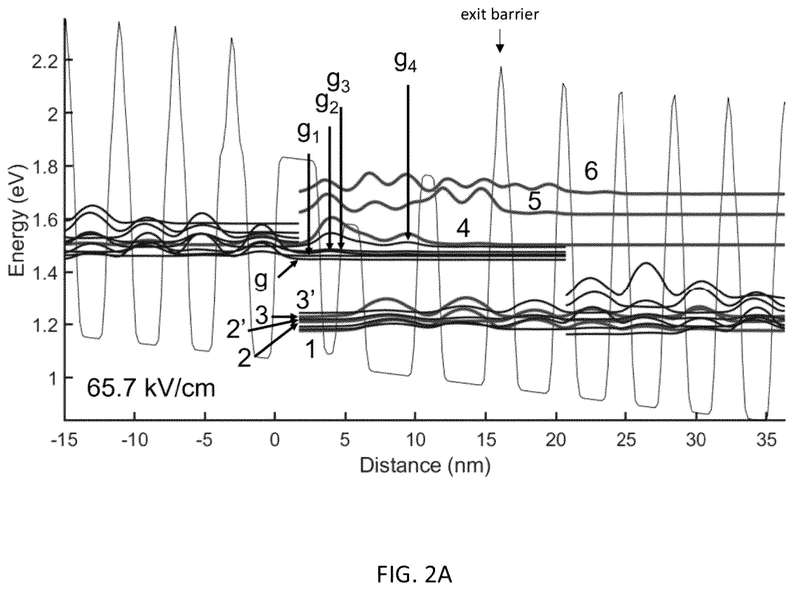

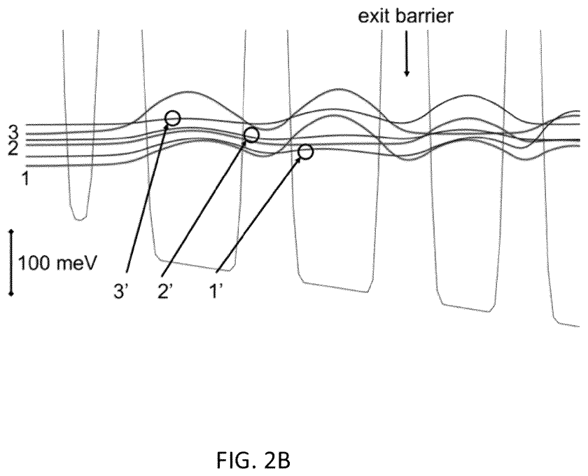

Conditions for strong PICT action include strong coupling (6-10 me V) between the injecting state and the ul level or that the injecting state, at threshold, is the ul level, a strong diagonal transition, and a very short ll-level lifetime, which, in turn, ensures quick gain recovery. FIGS. 2A and 2B show, at threshold, the schematic conduction-band (CB) diagram with graded interfaces and the relevant wavefunctions for the shallow-well, linear TA type device for the whole stage (FIG. 2A) and for the low-energy states in the optical transition region (FIG. 2B). It was observed that states 2 and 2′ have the same strong coupling (7.5 meV), at a resonance field of 66.8 keV (i.e., a detuning from threshold of only 1.1 kV/cm), as states g₄ and 4 do. Furthermore, as discussed below, at resonance the lasing transition primarily occurs from level g₄, while above resonance level 4 becomes the ul level, as it is injected in from level g₃. Therefore, it is concluded that, unlike in conventional QCLs, in these QCLs with strong PICT action, at threshold the ul level is a prior-stage low-energy state extending into the lasing stage, while above the resonance of that state with the next-higher-energy state, the latter becomes the ul level, and there is injection into it the over ˜8 barriers spanning both the prior stage and the current stage, via tunneling, in the presence of strong scattering, from a lower-energy prior-stage state. The ul level corresponding, at threshold, to a prior-stage low-energy state ensures a low applied field value at threshold, Fₜₕ, (i.e., 65.7 kV/cm) unlike conventional QCLs for which, after injection through the prior-stage exit barrier, electrons are scattered down to the injector ground state, g, and lasing starts at a higher field when g and the ul level reach the detuning value necessary for achieving population inversion via resonant-tunneling injection through only a single barrier. Therefore, lasing onset occurs at a relatively low applied field, Fₜₕ, which, in turn, allows for both a low threshold-voltage value as well as low thermal backfilling, as needed for efficient CW operation.

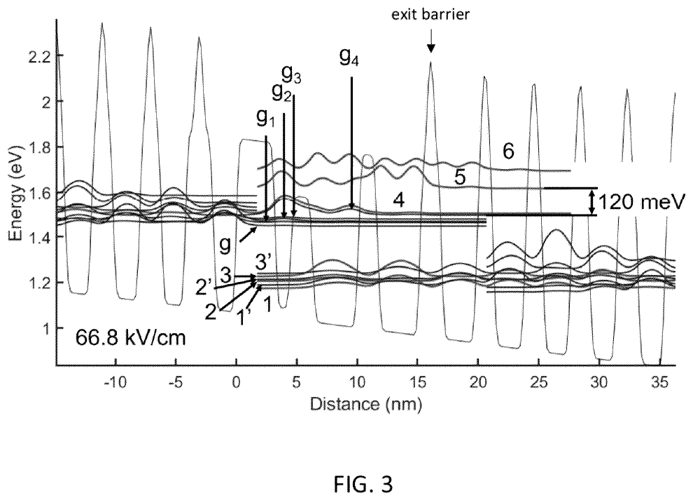

From FIG. 2A and FIG. 3 (i.e., at resonance) it is clear that there is a strong diagonal transition, and that at resonance states g₄ and 4 become degenerate, in that their wavefunctions strongly overlap.

The second condition for PICT action: strong diagonal transition, is also met. In this case, there is resonant extraction from the ll level, state 3. That is, state 3 strongly couples to the extractor state 3′, with an energy splitting of 10.5 meV at 72.6 kV/cm. This means that up to 72.6 kV/cm extractor state 3′ is another ll level. Thus, at threshold and at the g₄/4 resonance there are lasing transitions to both ll levels 3 and 3′. However, for this particular device, it is found that a dominant gain peak emerges only at resonance (i.e., at 1.1 kV/cm above Fₜₕ), which corresponds to a drive level of 1.4×Jₜₕ, with the ul level being state g₄. The respective dipole matrix elements are z_{g4,3}=5.9 Å and z_{g4,3}=3.2 Å, which give an overall matrix element z_{g4,ll}=6.7 Å; that is, a strong diagonal transition.

The third condition for PICT action: quick gain recovery is achieved, since the only time delay for reaching the ul level involves depopulation of the ll level, state 3: 1) via tunneling into extractor state 3′; 2) via relaxation to states 2, 2′, 1 and 1′ followed by tunneling into extractor states 2′ and 1′ (see schematic CB diagram and relevant wavefunctions in FIG. 2B). The global ll-level lifetime, τ_{ll,g}, characterizing relaxation to states 2, 2′, 1 and 1′, has a low value of 0.07 ps. This can be achieved using QCL structures with tall barriers on the downstream side of the AR, in which case IFR scattering dominates (e.g., for this device the IFR component of τ_{ll,g} is 0.10 ps). Extraction from levels 3, 2, 1 is ensured by strong coupling to states 3′, 2′ and 1′: 10.5 meV, 7.5 meV, 10.6 meV, respectively. Then, the low-energy optical transition region states (i.e., 1-3) together with the penetrating extractor states (i.e., 1′-3′) form a relatively wide (˜70 meV) miniband; thus, ensuring highly efficient extraction, as needed for quick gain recovery; that is, quick replenishing of the ul level population to compensate for its depletion via stimulated emission.

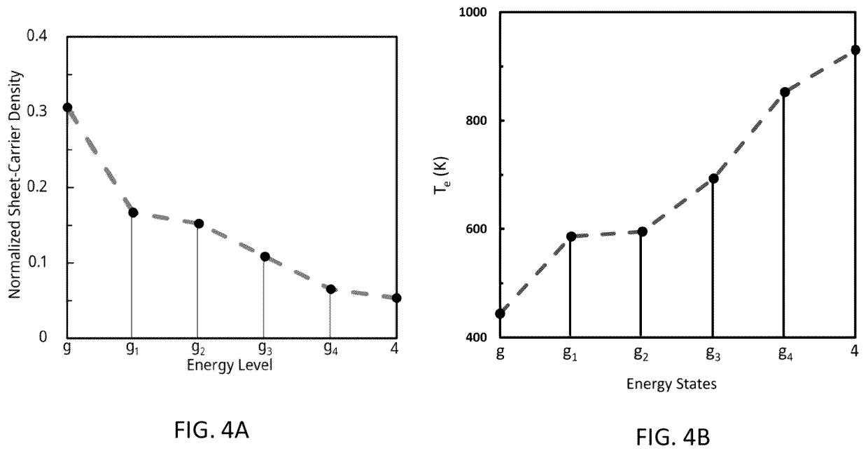

The modified NEGF analysis provides the sheet-carrier densities as well as the electron temperatures in each subband of interest. FIG. 4A shows the normalized sheet-carrier densities, and FIG. 4B shows the electron temperature (at 1.4×Jₜₕ), Tₑ. values for the energy states g, g₁, g₂, g₃, g₄ and 4. Notably the sheet-carrier densities in states g₄ and 4 are almost identical, as expected given that the two states are at the resonance. The electron temperatures generally increase with state energy, that is, a non-thermal population exists. In particular, the Tₑ, values for states g₄ and 4 are quite high (892 K on the average); that is, much higher than previously taken for thermalized subbands in the injector miniband. As will be revealed below, these high Tₑ values play a critical role in determining the carrier-leakage currents triggered by LO-phonon and IFR scattering from the ul level and the other states.

Finally, the global ul-level lifetime, τ_{ul,g}, has a high value of 2.3 ps, due to both the strong diagonal transition and the short (i.e., lattice-matched) barrier. The high τ_{ul,g} value together with the low τ_{ll,g} value lead to a high lasing-transition efficiency ηₜᵣ value of 97%, which is another reason behind the device's high WPE value. However, since 1.4×Jₜₕ, the τ_{ul,g} value is affected by the stimulated-emission lifetime, τₛₜᵢₘ, which is calculated to be 3.16 ps (see Supplementary Material, section C). Then, τ_{ul,g} decreases to 1.33 ps, the lasing-transition lifetime τ_{ul,ll} decreases from 5.29 ps to 1.98 ps, and, assuming that τ_{ll,g} (0.07 ps) hardly changes, the ηₜᵣ value decreases to 94.8%.

### Elastic Scattering and Carrier-Leakage Analysis

The modified NEGF analysis provides the Fₜₕ and resonance-field values (FIGS. 2A, 2B, and 3), the sheet-carrier densities, and the electron temperatures in relevant states and in the ul level (e.g., FIGS. 4A and 4B for the 4.9 μm-emitting QCL at resonance). Then, the previously developed comprehensive carrier-leakage formalism may be applied (C. Boyle, et al., Appl. Phys. Lett., vol. 117, no. 5, 051101, 2020; Erratum: Appl. Phys. Lett., vol. 117, no. 10, 109901, 2020). However, as discussed below, that formalism is valid only at threshold, while this QCL is analyzed at a drive level of 1.4×Jₜₕ. First, a 3-band k·p solver was employed to match the bands extracted from the modified NEGF analysis. However, for calculating relevant lifetimes the graded nature of the interfaces needs to be considered. Extending the theory of scattering by rough and graded interfaces to the multiband case, below, the expression of IFR scattering rate between a state m and a lower-energy state n, in heterostructures of structures of varying barrier and well compositions is generalized:

$$\frac{1}{{τ}_{mn}^{IFR}} = \frac{2 π}{ℏ} {\sum }_{\vec{q}} \frac{{πΛ}^{2}}{s} {e}^{- \frac{{Λ}^{2} {q}^{2}}{4}} {\vert {V}_{mn}^{( z )} \vert}^{2} δ ( {E}_{m} ( \vec{k} ) - {E}_{n} ( \vec{k} + \vec{q} ) ) \qquad ( 1 a )$$

$${\vert {V}_{mn}^{( z )} \vert}^{2} = {Δ}^{2} ( z ) {Σ}_{b} ( \begin{matrix}\int {dz}_{1} \int {dz}_{2} {φ}_{m , b}^{*} ( {z}_{1} ) {φ}_{m . b} ( {z}_{1} ) {φ}_{n , b}^{*} ( {z}_{2} ) {φ}_{n , b} ( {z}_{2} ) \\ \frac{\partial \overline{{V}_{b}}}{\partial z} ( {z}_{1} ) \frac{\partial \overline{{V}_{b}}}{\partial z} ( {z}_{2} ) {e}^{- \vert {z}_{2} - {z}_{1} \vert / {Λ}_{⊥}}\end{matrix} ) \qquad ( 1 b )$$

where V̅_̅{̅b̅}̅ is the in-plane-averaged potential associated with the band m, φ_{m,b}(z) is the component in band b of the m-state wavefunction along the growth direction, Δ(z) is the RMS height of isoconcentration surfaces, \vec{k} and \vec{q} are the initial and exchange in-plane wavevectors, respectively, z denotes the growth axis, and S is a normalization surface. The corresponding self-energies are implemented into the modified NEGF code, providing a full simulation of the simultaneous effects of roughness and grading. However, for the sake of the analysis, when the different interfaces are well separated with respect to the interfacial width, a scattering-rate reduction factor, F, due to graded interfaces can be defined:

$${\vert {V}_{m n}^{( z )} \vert}^{2} = F {\sum }_{i , b} {Δ}_{i}^{2} \int d {z}_{1} \int d {z}_{2} {φ}_{m , b}^{2} ( {z}_{i} ) {φ}_{n , b}^{2} ( {z}_{i} ) {\vert {δV}_{b i} \vert}^{2} \qquad ( 2 a )$$

$$F = exp [ \frac{{L}^{2}}{16 ln ( 2 ) {Δ}_{⊥}^{2}} ] [ erf [ - L / ( 4 \sqrt{ln ( 2 )} {Δ}_{⊥} ) ] + 1 ] \qquad ( 2 b )$$

where Δᵢ is the RMS height at the i^{th} interface and δV_{bi} is the CB offset at the i^{th} interface. For transitions from the ul level, m is the ul-level state number and n is the ll-level state number or the state number of any of the rest of low-energy optical transition region and extractor states. For transitions from the ll level(s), m is the ll-level state number and n is the state number of any of the lower-energy optical transition region and extractor states. For example, for the band diagram and wavefunctions shown in FIGS. 2A and 2B, m=g₄ and n=3, 3′, 2, 2′, 1 and 1′ for transitions from the ul level, state g₄; while m=3 and n=2, 2′, 1 and 1′ for transitions from the ll levels; where the primed states are extractor states. In the general 3-band case the effective-mass description is not appropriate anymore, unless defining energy-dependent effective masses. By using energy-dependent masses, the IFR scattering rate between a level m and a level n is:

$$\frac{1}{{τ}_{m n}^{IFR}} ≅ \frac{π}{{ℏ}^{3}} {Λ}^{2} F {m}_{c n} exp ( - \frac{{Λ}^{2} {m}_{c n} {E}_{m n}}{2 {ℏ}^{2}} ) {Σ}_{i} {Δ}_{i}^{2} δ {V}_{i}^{2} {φ}_{m}^{2} ( {z}_{i} ) {φ}_{n}^{2} ( {z}_{i} ) \qquad ( 3 )$$

where m_{c,n} is the energy-dependent effective mass of the lower-energy level, n; δVᵢ is the CB offset at the i^{th} interface, and φᵤₗ (zᵢ) and φₗₗ (zᵢ) are the wavefunction amplitudes of the ul or ll levels at the i^{th} interface. Eₘₙ represents the energy difference between states, and Λ is taken to be substantially the same at all interfaces, as observed from APT analysis.

For the QCL structure shown in FIGS. 2A and 2B (i.e., for L=0.4 nm and Λ_{⊥}=0.1 nm) F has a value of 0.38. The reduction of the scattering rate for graded interfaces vs. abrupt interfaces can be understood in view of the fact that a graded interface does not behave like a single scattering center, but instead acts as a collection of different, only partially correlated, scattering centers. That is, the degree of IFR scattering coherence is significantly reduced for graded interfaces vs. abrupt interfaces.

The alloy-disorder (AD) scattering rate between two selected states m and n, in a given ungraded well or barrier layer, is given in C. Boyle, et. al. However, for the graded regions between the ternary-alloy well and barrier layers, the AD scattering expression is quite complicated since it has to consider quaternary alloys composed of three group III elements and one group V element. Then, for a given AlₓIn_{y}Ga_{1-x-y}As graded interface, the total scattering rate between two selected states m and n is given by:

$$\frac{1}{{τ}_{mn}^{AD}} = \frac{1}{8} {\int }_{0}^{L} \frac{{m}_{c} ( z ) {a ( z )}^{3}}{{ℏ}^{3}} [ \text{} x ( z ) [ 1 - x ( z ) - y ( z ) ] [ 1 - y ( z ) ] {( {V}_{Al - Ga} )}^{2} + y [ 1 - x ( z ) - y ( z ) ] [ 1 - x ( z ) ] {( {V}_{In - Ga} )}^{2} + x ( z ) y ( z ) [ x ( z ) + y ( z ) ] {( {V}_{Al - In} )}^{2} + 2 x ( z ) y ( z ) [ 1 - x ( z ) - y ( z ) ] ( {V}_{Al - Ga} {V}_{In - Ga} + {V}_{Al - Ga} {V}_{Al - In} - {V}_{In - Ga} {V}_{Al - In} ) ] {φ}_{m}^{2} ( z ) {φ}_{n}^{2} ( z ) dz \qquad ( 4 a )$$

where V_{Al-Ga}=0.8 eV, V_{Al—In}=−0.6 eV, V_{In—Ga}=1.4 eV are the differences between the CB minima of the binary-alloy components, and a, the lattice parameter, is graded in accordance with Vegard's law:

$$a ( z ) = y ( z ) {a}_{InAs} + [ 1 - x ( z ) - y ( z ) ] {a}_{G a A s} + x ( z ) {a}_{A l A s} \qquad ( 4 b )$$

The integral is nontrivial to solve, so the graded interface is approximated in 0.1 nm-wide rectangular steps of compositions equal to those at the end of each step. Then, for each 0.1 nm-wide step, the following is calculated:

$${\frac{1}{{τ}_{mn}^{AD}} \vert}_{s} = \frac{1}{8} \frac{{m}_{cs} {a}_{s}^{3}}{{ℏ}^{3}} [ {x}_{s} ( 1 - {x}_{s} - {y}_{s} ) ( 1 - {y}_{s} ) {( {V}_{Al - Ga} )}^{2} + {y}_{s} ( 1 - {x}_{s} - {y}_{s} ) ( 1 - {x}_{s} ) {( {V}_{In - Ga} )}^{2} + {x}_{s} {y}_{s} ( {x}_{s} + {y}_{s} ) {( {V}_{Al - In} )}^{2} + 2 {x}_{s} {y}_{s} ( 1 - {x}_{s} - {y}_{s} ) ( {V}_{Al - Ga} {V}_{In - Ga} + {V}_{Al - Ga} {V}_{Al - In} - {V}_{In - Ga} {V}_{Al - In} ) ] {φ}_{ms}^{2} {φ}_{ns}^{2} \times 0.1 nm \qquad ( 5 )$$

where s is the step number (e.g., if L=0.4 nm the calculations are done for s=1, 2, 3, and 4), xₛ, yₛ are the quaternary-alloy Al and In fractions at the interface between step s and step s+1, and

$${φ}_{ms}^{2} , {φ}_{ns}^{2}$$

are the probability values of states m and n at the interface between step s and step s+1. The profiles for the graded interfaces, as displayed for instance in FIGS. 2A and 2B, follow an error function defined in T. Grange, et al., which is used to determine the lattice constant, αₛ, and the alloy fractions, xₛ and yₛ, at each step.

The LO-phonon- and IFR-triggered leakage-current densities,

$${J}_{l e a k}^{L O} and {J}_{l e a k}^{IFR} ,$$

from both the ul level and relevant states through high-energy optical transition region states down to low-energy optical transition region states are calculated as in C. Boyle, et al., except that, given the relatively high electron temperatures found in this Example, the exponential term in the

$${J}_{leak , mn}^{L O}$$

expression

$$[ i . e . , exp ( - \frac{{E}_{n m}}{k {T}_{e m}} ) ]$$

has to be replaced with

$$exp \{ - \frac{( {E}_{nm} + {ℏω}_{LO} [ ( {T}_{em} / T ) - 1 ] )}{{kT}_{em}} \} ,$$

where Tₑₘ is the electron temperature in state m, T is the lattice temperature, and ℏω_{LO} is the phonon energy. FIG. 5 shows a bar chart of the following: the total Jₗₑₐₖ value normalized to J (left bar); the total normalized

$${J}_{leak}^{LO}$$

value (middle bar); and the total normalized

$${J}_{leak}^{LO}$$

value in case of inelastic-only scattering from only the ul level, state g₄ (right bar). The calculation is done at resonance (i.e., at a field of 66.8 kV/cm), where J=1.4×Jₜₕ, since there the gain has one dominant peak, while Jₗₑₐₖ/J≅J_{leak,th}/J for J values close above threshold.

The analysis shows that leakage through the high-energy states 5 and 6 is mostly IFR triggered (i.e., the IFR part is 86% of the total leakage) and occurs mostly from the state g₄, and state 4. This is explained by the high average electron temperatures (˜892 K) in those energy states as well by the proximity, in energy, between those levels and the high-energy optical transition region levels 5 and 6. By contrast, the inelastic-only leakage from the ul level is only 5.4% of the total normalized leakage (i.e., 1.5% vs. 28%) showing that elastic scattering dominates carrier leakage in mid-IR QCLs. In this case, level 4 acts like a parasitic optical transition region state, just 7.5 meV above the ul level. There is more leakage from it than from level g₄, since it is 100 K hotter (i.e., 930 K vs. 853 K). Notably, the total normalized leakage through state 5 is basically the same as that calculated via abrupt-interfaces analysis (see C. Boyle et al.) of the same QCL structure (i.e., 17% vs. 18.5%), despite the inherent reduction in IFR scattering rates for graded-interfaces structures (i.e., F=0.38) and a higher energy difference between states 5 and 4, and 5 and g₄ (i.e., 113 and 120 meV) and states 5 and 4 for the latter case (i.e., 79 meV). This is attributed to much higher electron temperatures (i.e., ˜892 K vs. 347 K) as a result of employing the modified NEGF-based modeling.

However, as pointed out above, the stimulated lifetime has to be taken into account, in which case the ηₜᵣ value was estimated to be 94.8%. If there is no leakage and taking unity tunneling injection efficiency, the total injection efficiency, ηᵢₙⱼ, becomes unity. Then, the fundamental limit for the internal efficiency, ηᵢ, is the ηₜᵣ value (94.8%). Since the experimentally measured ηᵢ value was 70%, the differential pumping efficiency, ηₚ=1−Jₗₑₐₖ/J, had to be 73.8%; thus, giving a total normalized leakage of 26.2%. That is, considering stimulated emission, the normalized leakage is approximately 26% at 1.4× Jₜₕ.

The relatively large, normalized leakage values found (i.e., 26-28%) show that for the shallow-well, linear TA type QCL device examined in this section, carrier leakage is significant. Such high leakage was previously unknown and unexpected in view of the relatively high WPE value. The differential pumping efficiency, ηₚ, is 72-74%, and the total injection efficiency ηᵢₙⱼ is only 71-73%. Given that ηₜᵣ=94.8-97%, in the ideal case that ηᵢₙⱼ is unity, the fundamental upper limit for ηᵢ is the ηₜᵣ value, which leads, at λ=4.9 μm, to a WPE fundamental upper limit of 39-40%. Therefore, the present analysis reveals for the first that that not only that there is considerable room for further increasing the front-facet WPE value at λ˜4.9 μm (i.e., from 27% to values close to 40%), but also how to do so. As further demonstrated below, this can be achieved by designing graded-interface STA QCL structures with PICT action and virtually complete carrier-leakage suppression.

### Sensitivity Analysis to Variations in IFR Parameter Values (See Supplementary Material, Section B)

While keeping the A value constant at 6 nm, a sensitivity analysis to variations in IFR parameters' values on device performance reveals that the slope efficiency, ηₛₗ, is the most sensitive device characteristic to variations in the L/Λ_{⊥} value and in the Δ value. Maximum errors of +/−4% in the ηₛₗ value have been chosen as the criterion for a reasonably good fit to experimental data. The ηₛₗ value increases with increasing L/Λ_{⊥} value because less IFR-triggered carrier leakage is associated with increased L/Λ_{⊥} value (Supplementary Material, section B). Practically, L is not likely to be wider than 0.55 nm or narrower than 0.30 nm. Thus, for the L/Λ_{⊥} value that best fits the experimental data (i.e., 4) the Λ_{⊥} value may well be in the 0.08-0.14 nm range. The ηₛₗ value decreases with increasing Δ value because of increased IFR-triggered carrier leakage. These findings reveal, for the first time, the importance of minimizing the IFR-triggered carrier leakage as well as how to minimize such carrier leakage, e.g., by increasing L/Λ_{⊥} and decreasing Δ, in order to maximize the device pulsed and CW performance.

Comparisons to Results Obtained with Extracted Abrupt-Interface IFR Parameters

Using Λ=9 nm and Δ=0.12 nm, the Jₜₕ value increases from 1.3 kA/cm² to 2.2 kA/cm², since injection occurs from the 1^{st}-excited injector state into the ul level. There is no PICT action, as the device acts as a conventional QCL emitting at 4.5 μm (see Supplementary Material, section D).

High Front-Facet Wall-Plug Efficiency 8.3 μm-Emitting QCL

The device (Zhou, W. et al.) examined has a conventional-like QCL structure (i.e., quantum wells and barriers of fixed compositions) and (a) employs a diagonal transition, to maximize the ul-level lifetime; (b) use a low value of 90 meV for the voltage defect at resonance, Δ_{inj,res}; and (c) has a low waveguide loss (1.34 cm⁻¹). The front-facet maximum pulsed WPE value is 17%, at 293 K heatsink temperature.

### Modified NEGF-Based Analysis

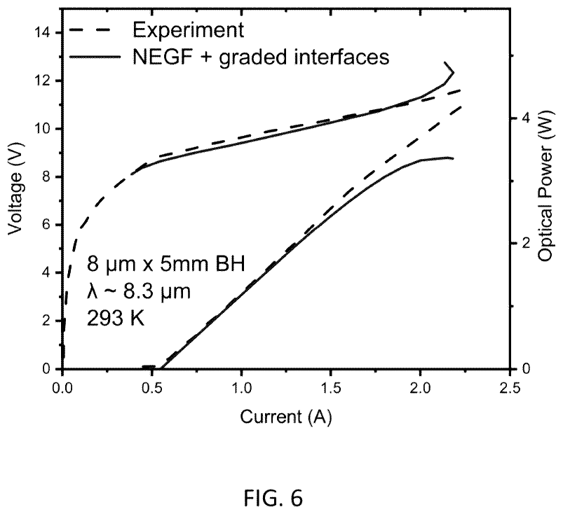

Again, the experimentally measured ˜6 nm value for Λ is used. Then, just as for the 4.9 μm-emitting QCL examined above, by matching the Jₜₕ value and the V-I curve, while considering values and trends found from APT analysis of mid-IR QCL structures, the following ac obtained: Δ=0.11 nm, L=0.4 nm, and Λ_{⊥}=0.1 nm. The smaller Δ value than for the moderately strained barriers' interfaces (i.e., Al_{0.64}In_{0.36}As/In_{0.69}Ga_{0.31}As) of 4.9 μm-emitting QCLs (i.e., 0.13 nm) may well reflect a lower degree of differential strain for the employed barriers (i.e., Al_{0.64}In_{0.36}As/In_{0.59}Ga_{0.41}As). The experimental V-I and L-I curves are compared in FIG. 6 to those generated via the modified NEGF-based model with graded interfaces. The calculated R_{diff} value: 1.65Ω, is very close to the 1.6Ω experimental value. However, the calculated Jₘₐₓ value (i.e., 5.45 kA/cm²) is lower than the experimental value (i.e., ˜5.7 kA/cm²). It is suspected that this difference in Jₘₐₓ values reflects inadvertent overdoping of the grown QCL structure. The L-I curve matches the experimental curve very well to ˜3× threshold. Despite the relatively small discrepancy in Jₘₐₓ values, to the best of the inventors' knowledge, this is the first time that the electro-optical characteristics of this QCL have been theoretically reproduced.

PICT action is evident from the fact the R_{diff} value is ˜60% of the R_{diff} for a conventional 8.4 μm-emitting QCL considering the same pumped area (i.e., ˜8 μm×5 mm). (A. Wittmann, et al., Appl. Phys. Lett., vol. 93, no. 14, 141103, 2008.) For the device's published nₛ value of 1.07×10¹¹ cm⁻², the Jₘₐₓ value for the conventional 8.4 μm-emitting QCLs is ˜4.7 kA/cm², given τₜᵣₐₙₛ˜3.6 ps; that is, the calculated Jₘₐₓ value is only ˜16% higher than for conventional devices. This relatively low enhancement in Jₘₐₓ value is most likely due both to a moderate splitting energy at resonance between levels, 2 and 2′ from the prior stage (i.e., 6.6 meV) as well as to a moderate degree of lasing-transition diagonality (i.e., z_{ul,ll}=16.4 Å).

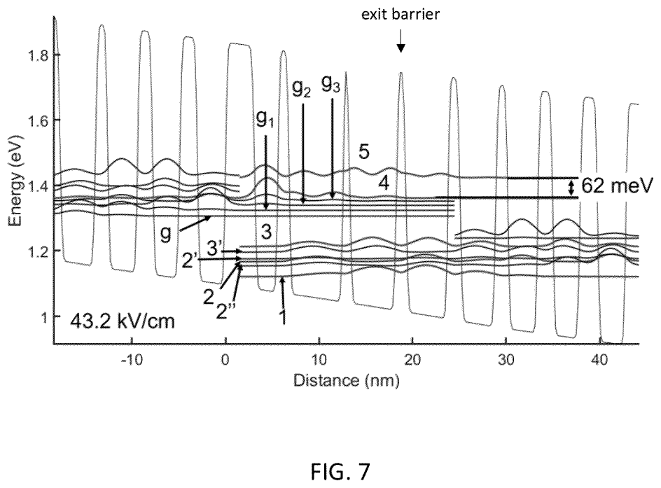

A schematic representation of the CB diagram and relevant wavefunctions are shown in FIG. 7. Injection occurs from the low-energy level 2, from the prior stage, directly into the ul level, state 4. As mentioned above, the states 2 and 2′ are moderately strong coupled (6.6 meV), and, just as for the 4.9 μm-emitting QCLs, laser action starts close to resonance (i.e., at 43.2 kV/cm vs. 45.3 kV/cm). Similarly, as for the 4.9 μm-emitting QCLs, there is strong extraction from the ll level, state 3, in that the 3-3′ splitting at resonance is 16.7 meV and it occurs close to threshold (i.e., at 42 kV/cm vs. 43.2 kV/cm). There is also strong extraction for state 2 via sequential coupling to: 1) extractor state 2″: 12.4 meV splitting at 39.7 kV/cm; and 2) extractor state 2′ (6.6 meV splitting at 45.3 kV/cm). Thus, the device has miniband-type extraction which, together with a 0.12 ps ll-level lifetime and a tunneling time into the ull of the order of ˜0.5 ps ensures quick gain recovery. At threshold, the ul level is state 4, unlike for the 4.9 μm-emitting QCL. At resonance, there is lasing from both the g₃ and 4 states, and above resonance lasing resumes solely from state 4.

The modified NEGF analysis shows non-thermal population as expected, in that the electron temperatures increase with increasing state energy. The most relevant electron temperatures at threshold, T_{e,th}, are for states g₃ and 4:395 K and 445 K, respectively. As seen below, these high T_{e,th} values cause the carrier leakage to be dominated by leakage from states 4 and g₃. It is also noted that the electron temperature in the ul level is comparable to that found via NEGF analysis of an 8.5 μm-emitting QCL (i.e., 512 K at ˜2×Jₜₕ), albeit for a device that had PICT action only as far as photon-driven transport in the optical-transition region, due to intentional weak coupling between the injector state and the ul level, to allow for wavelength tunability.

The ul-level lifetime is 0.99 ps which, together with the 0.12 ps ll-level lifetime, provides an ner value of 89%. For the ideal case of complete carrier-leakage suppression and unity tunneling injection efficiency, the ηₜᵣ value (i.e., 89%) represents the upper limit for ηᵢ. However, the experimentally obtained ηᵢ value was only 66% which, as we shall see below, is primarily due to strong carrier leakage.

### Carrier-Leakage Analysis

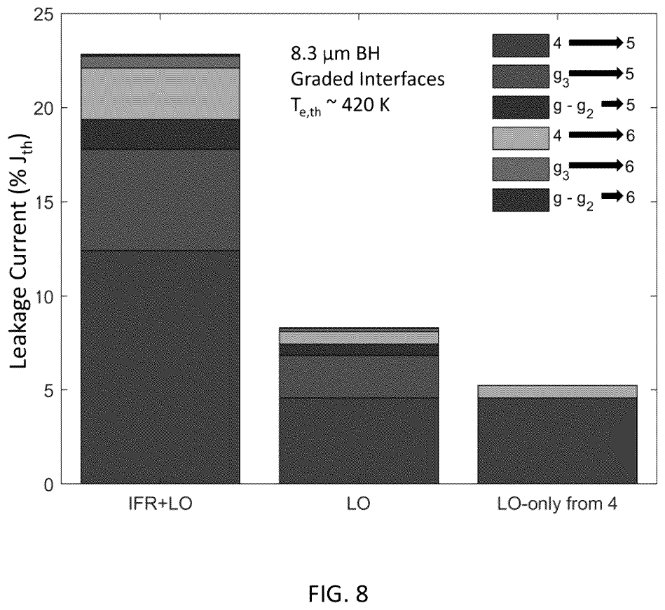

The analysis is done, just as for the 4.9 μm-emitting QCL examined above, by using the comprehensive carrier-leakage model with the relevant states' sheet-carrier densities and electron-temperatures as provided by the modified NEGF analysis, and using IFR- and AD-scattering rates for graded interfaces. FIG. 8 shows: the total Jₗₑₐₖ value normalized to Jₜₕ (left bar); the total normalized

$${J}_{leak}^{LO}$$

value (middle bar); and the total normalized

$${J}_{leak}^{LO}$$

value in case of measure starring only from the ul level, state 4 (right bar).

The total normalized leakage, Jₗₑₐₖ/Jₜₕ, reaches a value of 22.7%, which is due to the high T_{e,th} values in states g₃ and 4, and it occurs mostly through state 5 (i.e., a total leakage of ˜19%). The latter is due to a relatively low value of 62 meV for the energy difference between the state 5 and the ul level, state 4, E₅₄. The leakage is triggered mostly from states 4 and g₃, since they not only have the highest T_{e,th} values, but also the strongest wavefunction overlaps at interfaces with the state-5 wavefunction. Just as for the 4.9 μm-emitting QCL, the leakage is in large part IFR triggered.

Although the 8.3 μm QCL device exhibits PICT action, the present analysis reveals, for the first time, that there is considerable room for further increasing the front-face WPE value at this wavelength (i.e., from 17% to close to 25%) as well as how to do it. As further demonstrated below, this can be achieved by designing graded-interface STA QCL structures with PICT action and virtually complete carrier-leakage suppression.

### Sensitivity Analysis to Variations in IFR Parameter Values (See Supplementary Material, Section B)

While keeping the Λ value constant at 6 nm, sensitivity analyses to variations in the L/Λ_{⊥} value and in the Δ value on device performance reveal that the slope efficiency, ηₛₗ, is the most sensitive device characteristic. Maximum errors of +/−4% in the ηₛₗ value are chosen as the criterion for a reasonably good fit to experimental data. The ηₛₗ value increases with increasing L/Λ_{⊥} value because of less IFR-triggered carrier leakage (see Supplementary Material, section B). The ηₛₗ value decreases with increasing Δ value because of increased IFR-triggered carrier leakage. Again, these findings reveal the importance of minimizing the IFR-triggered carrier leakage as well as how to minimize such carrier leakage, e.g., by increasing L/Λ_{⊥} and decreasing Δ, in order to maximize the device pulsed and CW performance.

Comparisons to Results Obtained with Extracted Abrupt-Interface IFR Parameters

Using Λ=9 nm and Δ=0.10 nm, the Jₜₕ value increases from 1.37 kA/cm² to 1.98 kA/cm², since lasing starts at a higher field: 46.6 kV/cm. There is PICT action, but it is weaker than for the graded-interface case, as evidenced by a higher R_{diff} value: 1.9Ω, and a lower Jₘₐₓ value: 5.2 kA/cm² (see Supplementary Material, section D).

Design of an Illustrative 8.1 μm-Emitting STA-QCL with Significantly Enhanced Wall-Plug Efficiency

The CB diagram and relevant wavefunctions are shown in FIG. 9 for an illustrative 8.1 μm-emitting STA type QCL according to the present disclosure. In this design, the third barrier in the optical transition region of the 8.3 μm-emitting QCL (see FIG. 7) was replaced with an AlAs barrier. The same nominal sheet-doping density was used as the 8.3 μm-emitting QCL. Thus, the 8.1 μm-emitting STA type QCL has barriers that are stepwise tapered in the AR, which brings about two advantages as far as carrier-leakage suppression: increased E_{5,ul} value, and decreased overlap of the wavefunctions at interfaces for the ul level and the next higher optical transition region energy level, state 5. The same graded-interfaces' IFR parameters found above for the 8.3 μm-emitting QCL device were used, except that for the AlAs barrier A=0.17 nm was used.

### Modified NEGF-Based Analysis

As noted above, the CB diagram and relevant wavefunctions for the 8.1 μm-emitting STA type QCL are shown in FIG. 9. Notably, the E₅₄ value has increased from 62 meV to 91 meV. However, at threshold, the lasing transition occurs from state g₃, since injection from the prior-stage state 2 occurs into it; thus, the relevant energy difference is E_{5,g,3}, which is 101 meV. In this case, the lasing threshold occurs right at the resonances between the prior-stage states 2 and 2′, and between states g₃, and 4, respectively (i.e., at 42.5 kV/cm), as clearly evidenced by the virtual complete overlap of their respective wavefunctions. The splitting energy at resonance is 10.5 meV; thus, there is strong coupling. In addition, the device has a stronger diagonal lasing transition than the 8.3 μm-emitting QCL (i.e., the z_{ul,ll} value decreases from 16.7 Å to 9.2 Å). Thus, stronger PICT action is achieved. The modified NEGF analysis provides the non-thermal population, with T_{e,th} values for states g₃ and 4:414 K and 443 K, respectively. Due to the increased lasing-transition diagonality, the ul-level lifetime is 2.3 ps compared to 0.99 ps for the 8.3 μm-emitting device. Together with a 0.12 ps ll-level lifetime, the ηₜᵣ value is 94.8%.

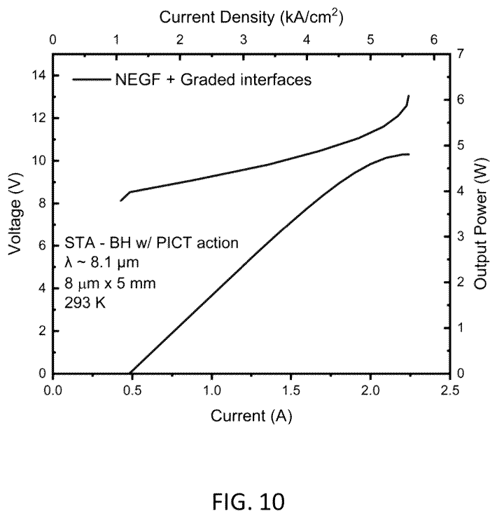

FIG. 10 shows the generated V-I and L-I curves for the 8.1 μm-emitting STA type QCL of the same pumped area, α_{w}, and αₘ values as for the 8.3 μm-emitting QCL. The stronger PICT action is evidenced by a lower calculated R_{diff} value: 1.5Ω vs. 1.65Ω, and by a higher calculated Jₘₐₓ value: 5.6 kA/cm² vs. 5.45 kA/cm². Now the Jₘₐₓ value is ˜20% higher than for conventional ˜8 μm-emitting QCLs of the same injector doping level. The maximum peak power is 4.8 W compared to 4.2 W for the 8.3 μm-emitting QCL.

### Carrier-Leakage Analysis

As mentioned above, carrier-leakage analysis was done by using the comprehensive carrier-leakage model with the relevant states' sheet-carrier densities and electron-temperatures as provided by the modified NEGF analysis, and using IFR- and AD-scattering rates for graded interfaces. The results are shown in FIG. 11.

The total normalized leakage, Jₗₑₐₖ/Jₜₕ, is just 12.5%; that is, ˜55% the value for the 8.3 μm-emitting QCL. The ηᵢₙⱼ value is 85% which, together with the ηₜᵣ value, results in an internal efficiency ηᵢ value of 80.5%. This is a significant improvement over the 66% value obtained for the 8.3 μm-emitting device. The higher ηᵢ value is reflected in a significant increase in slope efficiency; that is, 3.32 W/A (FIG. 10) vs. 2.6 W/A. Similarly, the decrease in carrier leakage is reflected in a lower Jₜₕ value: 1.21 kA/cm² vs. 1.37 kA/cm². This means that the absolute leakage-current density has dropped to 0.15 kA/cm² from 0.32 kA/cm²; i.e., it has basically halved. It is noted that the 8.1 μm-emitting STA type QCL is a preliminary structure examined for computational efficiency; the approach described in the present disclosure enables designs exhibiting Jₗₑₐₖ/Jₜₕ values as low as 5%.

### Wall-Plug Efficiency

As shown in FIG. 12, the combined effect of suppressed carrier leakage and stronger PICT action provides a front-facet maximum WPE value of 22.2% for the 8.1 μm-emitting STA type QCL as compared to the WPE value of 17% for the 8.3 μm-emitting device. Thus, a value close to the fundamental limit of ˜25% is achieved.

### Conclusions

This Example has demonstrated that the inventors' modified NEGF-based analysis revealed key features for maximizing the wall-plug efficiency, including direct injection from a prior-stage, low-energy optical transition region state into the upper-laser level of the optical transition region of a given stage, and strong photon-induced carrier transport. Regarding direct injection and unlike conventional QCLs, carrier injection occurs over multiple barriers into the upper-laser level via coherent and incoherent tunneling from the prior stage low-energy optical transition region state.

The Example also shows that despite high wall-plug efficiency values for the existing infrared QLCs (27% at λ˜4.9 μm and 17% at λ˜8.3 μm), there is significant normalized leakage-current density: 26-28% and 22.7% respectively, due in large part to high average electron temperature for the upper-laser level and an energy state adjacent to it: 890 K and 419 K, respectively. This means there is significant room for improvement via carrier-leakage suppression so as to achieve the fundamental upper limits in wall-plug efficiency: ˜40% at λ˜4.9 μm and ˜25% at λ˜8.3 μm. Given its accuracy, the inventors' modified NEGF-based analysis and carrier-leakage formalism becomes the design tool to reach these performance goals. By way of illustration, the new QCL-design tool was used to show that a preliminary design for an 8.1 μm-emitting QCL with significant carrier-leakage suppression reached a maximum wall-plug efficiency of 22.2%; thus, close to the ˜25% upper limit.

### Supplementary Materials

A. Experimental Data from 4.6 μm-Emitting QCL Designed with the Graded-Interfaces Model

A 4.6 μm-emitting STA-type QCL device (Botez, D., et al., IEEE J. Sel. Top. Quantum Electron., vol. 19, no. 4, 1200312, 2013; Correction: IEEE J. Sel. Top. Quantum Electron., vol. 19, no. 4, 9700101, 2013) was examined both experimentally and using the inventors' modified NEGF-based analysis with the following IFR parameters (as determined from APT-results analysis): Δ=0.14 nm at moderately strained AlInAs-barrier interfaces, and 0.2 nm at highly strained (i.e., AlAs) barrier interfaces; Λ=6 nm; and L=0.55 nm. In addition, a value of 0.1 nm was assumed for Λ_{⊥}. MOCVD-grown wafers, with a nominal injector doping ηₛ=1.04×10¹¹ cm⁻², were processed into 20 μm-wide ridges with HR-coated rear facets and provided the following electro-optical characteristics as determined experimentally: Jₜₕ=1.25 kA/cm²; slope efficiency, ηₛₗ=4.65 W/A; R_{diff}=1.3Ω, and a maximum front-facet wall-plug efficiency, η_{wp,max}=17.6%. By comparison, the values predicted by the model were: Jₜₕ=1.24 kA/cm²; ηₛₗ=4.27 W/A; R_{diff}=1.34Ω, and η_{wp,max}=18%. The comparison was made from plots of L-I-V curves and Wall-plug efficiency vs. I curves (data not shown).

The comparison showed that there was good agreement between experiment and theory. The experimental V-I curve displayed strong PICT action, in that R_{diff}=1.3 (2; that is, 55% of that for conventional QCLs of same pumped area (i.e., 2.33Ω), and a Jₘₐₓ value of 5.85 kA/cm²; that is, 1.35 times higher than that for conventional 4.6 μm-emitting QCLs of same injector doping level (i.e., 4.35 kA/cm²). These comparisons confirm the accuracy of both the graded-interfaces model and the IFR parameters obtained from analysis of APT results.

In addition, material from the same wafer was processed into narrow (6 μm) buried-heterostructure (BH), 5 mm-long chips with HR-coated rear facets and 10%-coated front facets.

The narrow-buried ridge was used for obtaining single-spatial-mode operation. L-I-V and WPE-I curves were obtained (data not shown). The experimental results showed that a front-facet η_{wp,max} value of 19.1% was obtained, which is higher than the best front-facet results reported to date from vertical-transition (i.e., no PICT action) 4.6-5.0 μm-emitting QCLs (i.e., 15.1% and 14%). However, the result is lower than the value obtained from the 4.9 μm-emitting QCL examined above. This difference is attributed to two issues: (a) the 4.6 μm-emitting STA-type QCL device has one parasitic, hot state above the ul level; thus, the calculated relative carrier-leakage density, Jₗₑₐₖ/Jₜₕ, at threshold, is rather high: ˜23%; (b) the crystal-growth conditions were not optimized for a low waveguide loss, α_{w} (i.e., ˜0.5 cm⁻¹). Thus, with further design optimization for low relative leakage (e.g., ≤15%) as described herein, and optimization of the crystal-growth conditions for lowering the α_{w} value, the η_{wp,max} value will significantly increase. An improved, illustrative QCL device is described in Example 2, below.

B. Sensitivity Analysis to Variations in IFR Parameters on the Performance of the 4.9 μm- and 8.3 μm-Emitting QCLs

The in-plane correlation length A was kept constant at 6 nm, as per its experimental determination from APT-results analysis of the 4.6 μm-emitting STA-type QCL structure. It is also worth noting that the A value of ˜0.135 nm, measured for moderately strained AlInAs/InGaAs interfaces, justifies the selection of a value of 0.13 nm for virtually identical moderately strained AlInAs/InGaAs interfaces of the 4.9 μm-emitting QCL structure. That leaves as the only IFR parameters which have been extracted by matching the Jₜₕ and L-I-V curves: the graded-interfaces' width, L, and the axial correlation length, Al. However, the scattering-rate reduction factor due to graded interfaces, F, is the only function of those parameters, and, furthermore, is a function of their ratio. Thus, the analysis was done as a function of variations in the L/Λ_{⊥} value.

It was found that the slope efficiency, ηₛₗ, was the most sensitive parameter to variations in L/Λ_{⊥} and Δ values. A tolerable variation in the ηₛₗ value was set to +/−4%.

B.1.1 4.9 μm-Emitting QCL

Since this device (Bai, Y., et al.) was found to operate in a dominant gain peak at a drive level ˜1.4×Jₜₕ, corresponding to lasing transitions from state g₄ to the lower-laser (ll) levels 3 and 3′, as well as to the resonance field between states g₄ and 4, calculations were done at the g₄/4 resonance points for each L/Λ_{⊥} value. The results are summarized in Tables S1 and S2.

TABLE S1
Changes in ηₛₗ with varying the L/Λ_{⊥} value.

| | | | Jₘₐₓ | | | Jₗₑₐₖ/ | | ηₛₗ × | |
|---|---|---|---|---|---|---|---|---|---|
| L/ | | λ | (kA/ | ηₛₗ | ηₜᵣ | J | ηₚ | η_{p/}ηₚ | Error |
| Λ_{⊥} | ×Jₜₕ | (μm) | cm²) | (W/A) | (%) | (%) | (%) | (W/A) | (%) |
| 3 | 1.3 | 4.7 | 5.65 | 5.47 | 97 | 32.6 | 67 | 5.35 | −2.2 |
| 3.5 | 1.5 | 4.72 | 5.75 | 5.56 | 96.9 | 31.1 | 69 | 5.47 | −1.6 |
| 4 | 1.4 | 4.8 | 5.76 | 5.72 | 97 | 28 | 72 | | |
| 4.5 | 1.5 | 4.8 | 5.83 | 5.94 | 96.5 | 24.7 | 75 | 5.98 | +0.7 |
| 5 | 1.6 | 4.84 | 5.9 | 5.96 | 96 | 23.2 | 77 | 6.1 | +2.3 |

First, the results show that the ηₛₗ value varies within +/−4% with respect to the value found to match experiment (i.e., 5.72 W/A for L/Λ_{⊥}=4); that is, the ηₛₗ value is:

$$5.72 W / {A}_{- 2.8 \%}^{+ 3.8 \%} ,$$

for the range

$$L / {Λ}_{⊥} : {4}_{- 0.5}^{+ 0.5} .$$

The reason behind the ηₛₗ variations are variations in the differential pumping efficiency ηₚ=1−(Jₗₑₐₖ/J), since ηₛₗ∝ηₜᵣηₚ, while the lasing-transition efficiency, ηₜᵣ, hardly varies with L/Λ_{⊥}. This happens because variations in the IFR components of both the global upper-laser (ul)- and ll-level lifetimes, τ_{ul,g} and τ_{ll,g}, cause the ratio τ_{ll,g}/τ_{ul,g} to hardly vary. Also shown in the table is a comparison of scaled ηₛₗ values with ηₚ with respect to the L/Λ_{⊥}=4 case. As can be seen, the errors are ≤1.6% over the acceptable range in L/Λ_{⊥}

$$( i . e . , {4}_{- 0.5}^{+ 0.5} )$$

and ≤2.3% over the entire L/Λ_{⊥} range. It is concluded that ηₛₗ ∝ηₚ; i.e., that ηₛₗ variations are due to relative carrier-leakage variations. Why this happens is evident from Table S2 and its discussion, below.

TABLE S2
$Table S 2 : Changes in {J}_{l e a k}^{IFR} with varying the F .$

| L/Λ_{⊥} | ${J}_{l e a k}^{IFR} / J ( \% )$ | ${J}_{l eak}^{IFR} ( kA / {cm}^{2} )$ | F | ${J}_{l e a k}^{IFR} \times F / F ( kA / {cm}^{2} )$ | Error (%) |
|---|---|---|---|---|---|
| 3 | 27.5 | 0.46 | 0.456 | 0.52 | +13 |
| 3.5 | 26.1 | 0.52 | 0.414 | 0.47 | −9.6 |
| 4 | 23.4 | 0.43 | 0.378 | | |
| 4.5 | 20.1 | 0.42 | 0.348 | 0.396 | −5.7 |
| 5 | 18.7 | 0.39 | 0.321 | 0.365 | −6.4 |

As noted above, it was established that ηₛₗ ∝ηₚ. The ηₚ term varies with changes in the Jₗₑₐₖ/J ratio, but only the IFR part of Jₗₑₐₖ,

$${J}_{leak}^{IFR} ,$$

varies with L/Λ_{⊥}. It is found that the percentage of Jₗₑₐₖ that corresponds to

$${J}_{leak}^{IFR}$$

is basically constant over the

$${4}_{- 0.5}^{+ 0.5}$$

range in L/Λ_{⊥}:

$${84}_{+ 0}^{- 2} \% ,$$

so its impact on the ηₛₗ value is the same over the

$${4}_{- 0.5}^{+ 0.5}$$

range. Next, the expression for

$${J}_{leak}^{IFR}$$

is examined:

$${J}_{leak , ul , 5}^{IFR} = \frac{{en}_{ul}}{\begin{matrix}IFR \\ 5 , ul\end{matrix}} \frac{\begin{matrix}LO , IFR , AD \\ 5 , tot\end{matrix}}{\begin{matrix}LO , IFR , AD \\ 5 , leak\end{matrix}} {I}_{nm} ( \frac{{E}_{5 , ul}}{{kT}_{e , ul}} ) exp ( \frac{{E}_{5 , ul}}{{kT}_{e , ul}} ) \qquad ( S1a )$$

where IFR-triggered leakage from the ul level (i.e., g₄) through the optical transition region state 5 is considered. The IFR backscattering rate from state 5 to state g₄ is obtained from Eq. (3) above, and shown below:

$$\frac{1}{{τ}_{5 , g4}^{IFR}} ≅ \frac{π}{{ℏ}^{3}} {Λ}^{2} {Fm}_{cg 4} exp ( - \frac{{Λ}^{2} {m}_{cg 4} {E}_{5 , g 4}}{2 {ℏ}^{2}} ) {\sum }_{i} {Δ}_{i}^{2} {δ V}_{i}^{2} {φ}_{5}^{2} ( {z}_{i} ) {φ}_{g 4}^{2} ( {z}_{i} ) \qquad ( S1b )$$

Over the

$${4}_{- 0.5}^{+ 0.5}$$

range: (a) the interface overlap factor (IOF):

$${\sum }_{i} {φ}_{5}^{2} ( {z}_{i} ) {φ}_{g 4}^{2} ( {z}_{i} ) ,$$

value is found to vary little:

$${1.78}_{- 0.09}^{+ 0.09} \times {10}^{- 4} ,$$

and (b) the E_{5,g4} value varies negligibly:

$$11 {9}_{- 1}^{+ 1} meV .$$

### Therefore,

$$1 / {τ}_{5 , g 4}^{IFR}$$

is expected to be basically proportional with the F factor Looking next at Eq. (S1a) it is found that: (a) nᵤₗ varies negligibly:

$${5.66}_{+ 0.02}^{- 0.02} \times {10}^{9} {cm}^{- 2} ;$$

(b) the lifetime ratio, which is the percentage of the carriers excited to state 5 which relax to all lower-optical transition region and extractor states (i.e., leaked carriers out of excited carriers), also varies negligibly:

$${26}_{- 0.7}^{+ 0.7} \% ;$$

(c) the E_{5,g4}/T_{e,g4} value varies as such:

$${0.118}_{- 0.01}^{- 0.003} meV / K .$$

The term I_{5,g4} has been found to be a weak function of both temperature and excitation energy, E_{5,g4}. Therefore, since

$$1 / {τ}_{5 , g 4}^{IFR}$$

is proportional will the F factor,

$${J}_{leak , g 4 , 5}^{IFR}$$

is expected to be basically proportional with F. Also shown in the table is a comparison of scaled values of

$${J}_{leak , g 4 , 5}^{IFR}$$

with F with respect to the F value for the L/Λ_{⊥}=4 case. The errors with respect to calculated values are: −5.7% and −9.6%. Therefore,

$${J}_{leak , g 4 , 5}^{IFR}$$

is reasonably proportional with F. Much smaller errors are expected if the drive currents were identical, as is seen below for the 8.3 μm-emitting QCL, for which all calculations were performed at the same drive level; that is, at threshold.

Given ηₛₗ ∝ηₚ, since ηₚ=1−(Jₗₑₐₖ/J) and

$${J}_{leak}^{IFR}$$

is ≅84% of Jₗₑₐₖ, the ηₛₗ value variations

$$( i . e . , 5.72 W / {A}_{- 2.8 \%}^{+ 3.8 \%} )$$

can be directly attributed to variations in the F factor. In turn, the F factor is inversely proportional with L/Λ_{⊥} (data not shown), since it was found that wider graded regions lead to reductions in the IFR scattering rate. In short, since an increase in L/Λ_{⊥} leads to less IFR-triggered carrier leakage, the ηₛₗ value increases with increasing L/Λ_{⊥} value. This explains the ηₛₗ increase with L/Λ_{⊥} in Table S1.

The other changes over the

$${4}_{- 0.5}^{+ 0.5}$$

range in L/Λ_{⊥} were small. For Jₘₐₓ:

$${5.76}_{- 0.01}^{+ 0.07} kA / {cm}^{2} ,$$

which corresponds to variations of only +1.2% and −0.2%, since the coupling between the injecting states 2 and 2′, and the g₄ and 4 states stays basically the same: 7.5 meV. Practically, L is unlikely to be wider than 0.55 nm or narrower than 0.30 nm. Thus, for the L/Λ_{⊥} value that best fits experimental data (i.e., 4) the Λ_{⊥} value may well be in the 0.08-0.14 nm range.
B.1.2 8.3 μm-Emitting QCL

This device (Zhou, W., et al.) was found to operate in a dominant gain peak at a threshold, corresponding to lasing transitions from state 4 to the ll levels 3 and 3′. The resonance is at 2.3 kV/cm above threshold, where there are comparable gain peaks for transitions from both states 4 and g₃, and then above resonance lasing from state 4 returns to be the dominant one. This behavior reflects initial injection from state 2 of the prior stage into the ul level, state 4, as opposed to injection from state 2 into the ul level, state g₃, for the illustrative 8.1 μm-emitting QCL according to the present disclosure. The results are summarized in Tables S3 and S4.

TABLE S3
Changes in ηₛₗ with varying the L/Λ_{⊥} value.

| | Jₜₕ | Jₘₐₓ | | | | | ηₛₗ × | |
|---|---|---|---|---|---|---|---|---|
| L/ | (kA/ | (kA/ | ηₛₗ | ηₜᵣ | Jₗₑₐₖ/ | ηₚ | η_{p/}ηₚ | Error |
| Λ_{⊥} | cm²) | cm²) | (W/A) | (%) | Jₜₕ | (%) | (W/A) | (%) |
| 3 | 1.39 | 5.32 | 2.53 | 89.2 | 26.2 | 73.8 | 2.51 | −0.8 |
| 3.5 | 1.37 | 5.46 | 2.57 | 89 | 24.6 | 75.4 | 2.57 | 0 |
| 4 | 1.37 | 5.45 | 2.61 | 88.9 | 23.3 | 76.7 | | |
| 4.5 | 1.37 | 5.45 | 2.65 | 88.7 | 22 | 78.0 | 2.65 | 0 |
| 5 | 1.37 | 5.43 | 2.67 | 88.7 | 21.2 | 79.0 | 2.69 | +0.7 |
| 6 | 1.34 | 5.4 | 2.8 | 88 | 17.2 | 82.8 | 2.82 | +0.7 |

First, the results show that the ηₛₗ value varies within +/−4% with respect to the value found to match experiment (i.e., 2.61 W/A for L/Λ_{⊥}=4). More specifically, the nst value is:

$$2.61 W / {A}_{- 3.1 \%}^{+ 2.3 \%}$$

for the range in L/Λ_{⊥}:

$${4}_{- 1}^{+ 1} .$$

The reason behind the ηₛₗ variations is due to variations in the differential pumping efficiency ηₚ=1−(Jₗₑₐₖ/J), since ηₛₗ∝ηₜᵣηₚ, while the lasing-transition efficiency ηₜᵣ hardly varies with L/Λ_{⊥}, just like for the 4.9 μm-emitting device. As can be seen, the errors are ≤0.8% over both the acceptable range in L/Λ_{⊥}

$$( i . e . , {4}_{- 1}^{+ 1} )$$

and over the entire L/Λ_{⊥} range. It is concluded that ηₛₗ∝ηₚ; i.e., that ηₛₗ variations are due to relative carrier-leakage variations. Why does this happen is evident from Table S4 and its discussion, below.

TABLE S4
$Table S 4 : Changes in {J}_{l e a k}^{IFR} with varying the F factor .$

| L/Λ_{⊥} | ${J}_{l e a k}^{IFR} / {J}_{th} ( \% )$ | ${J}_{l eak}^{IFR} ( kA / {cm}^{2} )$ | F | ${J}_{l e a k}^{IFR} \times F / F ( kA / {cm}^{2} )$ | Error (%) |
|---|---|---|---|---|---|
| 3 | 16.5 | 0.23 | 0.456 | 0.23 | 0 |
| 3.5 | 15.1 | 0.21 | 0.414 | 0.21 | 0 |
| 4 | 13.93 | 0.19 | 0.378 | | |
| 4.5 | 12.86 | 0.176 | 0.348 | 0.175 | −0.6 |
| 5 | 12.08 | 0.165 | 0.321 | 0.16 | −2.4 |
| 6 | 9.33 | 0.125 | 0.276 | 0.14 | +12 |

As for the 4.9 μm-emitting device, the table shows a comparison of scaled values of

$${J}_{leak , 45}^{IFR}$$

with F with respect to the F value for the L/Λ_{⊥}=4 case. The errors with respect to calculated values are: −0% and −2.4%; that is, significantly much lower than for the 4.9 μm-emitting device, since that comparison was done for data at somewhat different drive levels above threshold, while this is done at threshold [As seem from Table S3, Jₜₕ is basically the same over the acceptable range in L/Λ_{⊥}

$$( i . e . , {4}_{- 1}^{+ 1} ) ] .$$

### Therefore, the

$${J}_{leak , g 4 , 5}^{IFR}$$

value is very accurately proportional with F.

Given ηₛₗ ∝ηₚ, since ηₚ=1−(Jₗₑₐₖ/J) and it was found that

$${J}_{leak}^{IFR} / {J}_{th}$$

is

$$6 {0}_{+ 3}^{- 3} \%$$

of Jₗₑₐₖ/Jₜₕ, the ηₛₗ value variations

$$( i . e . , 2.61 W / {A}_{- 3.1 \%}^{+ 2.3 \%} )$$

can be directly attributed to variations in the F factor. Then, the same conclusion is reached as for the 4.9 μm-emitting device: the ηₛₗ value increases with increasing L/Λ_{⊥} value because less IFR-triggered carrier leakage is associated with increasing L/Λ_{⊥} value. As for Jₘₐₓ, just as for the 4.9 μm-emitting QCL, the variations are small:

$$5.45 kA / {{cm}^{2}}_{- 2.4 \%}^{- 0.4 \%} .$$

As mentioned above, practically, L is not likely to be wider than 0.55 nm or narrower than 0.30 nm. Thus, just as for the 4.9 μm-emitting device, for the L/Λ_{⊥} value that best fits the experimental data (i.e., 4) the Λ_{⊥} value may well be in the 0.08-0.14 nm range.

### B.2 Analysis of Device Performance to Variations in the Δ Value

B.2.1 4.9 μm-Emitting QCL
B.2.1.1 Varying-Δ Device vs. Uniform-Δ Device

The device that matched experimental data had Δ values of 0.10 nm, 0.13 nm and 0.17 nm for the interfaces of the short lattice-matched barrier, moderately strained barriers, and the tall heavily strained exit barrier, respectively. Table S5 shows a comparison to a device of same Δ value: 0.13 nm, for the interfaces of all barriers.

TABLE S5
Changes in ηₛₗ for the varying-Δ case vs. the uniform-Δ case.

| | | | Jₘₐₓ | ηₛₗ | | Jₗₑₐₖ/ | | ηₛₗ × | |
|---|---|---|---|---|---|---|---|---|---|
| Δ | | λ | (kA/ | (W/ | ηₜᵣ | J | ηₚ | η_{p/}ηₚ | Error |
| (nm) | ×Jₜₕ | (μm) | cm²) | A) | (%) | (%) | (%) | (W/A) | (%) |
| 0.13 | 1.4 | 4.8 | 5.73 | 5.57 | 96.9 | 29.8 | 70.2 | 5.58 | +0.2 |
| 0.1- | 1.4 | 4.8 | 5.76 | 5.72 | 97.1 | 27.9 | 72 | | |
| 0.13- | | | | | | | | | |
| 0.17 | | | | | | | | | |

The ηₛₗ value decreases with the pumping efficiency ηₚ (with an error of only 0.2%) when going from the varying-Δ case to the uniform-Δ case, since the lasing-transition efficiency ηₜᵣ stays basically the same. This fact is counterintuitive. On the one hand, although the low-Δ, lattice-matched barrier significantly lengthens the IFR part of the ul-level lifetime (i.e., from 10.9 ps in the uniform-Δ case to 13.9 ps in the varying-Δ case) the effective global ul-level lifetime, τ_{up,g}, increases slightly (from 2.18 ps to 2.28 ps) since LO and AD scattering primarily determine the ul-level lifetime for 4.5-5.0 μm-emitting QCLs. On the other hand, the high-Δ tall exit barrier shortens the IFR part of the global ll-level lifetime,

$${τ}_{ll , g}^{IFR} ,$$

albeit negligibly (from 0.106 ps to 0.102 ps); thus, the ll-level lifetime stays basically the same (0.07 ps). In turn, the ratio τ_{ll,g}/τ_{up,g} decreases slightly, leading to a small increase in the ηₜᵣ value (0.2%).

The actual impact of the low-Δ, lattice-matched barrier is to shorten the

$$1 / {τ}_{5 , ul}^{IFR}$$

part of the IFR-triggered leakage current [see Eqs. (S1a) and (S1b)] (i.e., from 1.05 ps⁻¹ to 0.92 ps⁻¹), thus decreasing

$${J}_{l e a k}^{IFR}$$

by ˜13%, which leads to a 2.6% increase in ηₚ, the actual increase in slope efficiency. That is, going from the uniform-Δ structure to the varying-Δ structure accounts for the almost 3% increase in the ηₛₗ value, which matches experiment (i.e., 5.76 W/A).

### B.2.1.2 Effect of Varying the Δ Value of the Moderately Strained Barriers' Interfaces

Table S6 shows a comparison between devices of three different Δ values: 0.12 nm, 0.13 nm and 0.14 nm, for the interfaces of moderately strained barriers.

TABLE S6
Changes in ηₛₗ for varying Δ value of the interfaces
bounding the moderately strained barriers.

| | | | Jₘₐₓ | ηₛₗ | | Jₗₑₐₖ/ | | ηₛₗ × | |
|---|---|---|---|---|---|---|---|---|---|
| Δ | | λ | (kA/ | (W/ | ηₜᵣ | J | ηₚ | η_{p/}ηₚ | Error |
| (nm) | ×Jₜₕ | (μm) | cm²) | A) | (%) | (%) | (%) | (W/A) | (%) |
| 0.1- | 1.5 | 4.8 | 5.83 | 5.94 | 96.8 | 25 | 75 | 5.96 | +0.3 |
| 0.12- | | | | | | | | | |
| 0.17 | | | | | | | | | |
| 0.1- | 1.4 | 4.8 | 5.76 | 5.72 | 97.1 | 27.9 | 72 | | |
| 0.13- | | | | | | | | | |
| 0.17 | | | | | | | | | |
| 0.1- | 1.35 | 4.8 | 5.66 | 5.5 | 97.2 | 30.9 | 69.1 | 5.49 | −0.2 |
| 0.14- | | | | | | | | | |
| 0.17 | | | | | | | | | |

First, it is noted that the 0.10-0.13-0.17 case matches best with the experimental values for ηₛₗ and Jₘₐₓ (i.e., 5.72 W/A and ˜5.75 kA/cm²). The ηₛₗ value varies within the +/−4% range with respect to the value found to match experiment. More specifically, the ηₛₗ value is:

$$5.72 W / {A}_{+ 3.9 \%}^{- 3.9 \%}$$

for the range in Δ for moderately strained barriers' interfaces:

$${0.13}_{- 0.01}^{+ 0.01} nm .$$

These variations are due to variations in the differential pumping efficiency ηₚ=1−(Jₗₑₐₖ/J), since ηₛₗ ∝ηₜᵣηₚ, while the lasing-transition efficiency ηₜᵣ hardly varies with Δ. The latter, just as in the previous subsection, is due to the fact that the variations in Δ, while affecting the IFR part of the ul-level lifetime

$$( 13 . {9}_{+ 0.12}^{- 0.11} ps ) ,$$

lave a negligible effect on the τ_{ll,g}/τ_{up,g} ratio. Scaling ηₛₗ values with ηₚ with respect to the 0.10-0.13-0.17 case gives errors≤0.3%; thus, the conclusion is that ηₛₗ ∝ηₚ. The reason behind this behavior is clarified from data in Table S7.

TABLE S7
$Table S 7 : Changes in {J}_{l e a k}^{IFR} with varying the {Δ}^{2} value of the moderately strained$
barriers' interfaces.

| Δ (nm) | ${J}_{l e a k}^{IFR} / J ( \% )$ | ${J}_{l eak}^{IFR} ( kA / {cm}^{2} )$ | ${J}_{l eak}^{IFR} \times {Δ}^{2} / {Δ}^{2} ( kA / {cm}^{2} )$ | Error (%) |
|---|---|---|---|---|
| 0.1-0.12-0.17 | 20.13 | 0.39 | 0.36 | −7.7 |
| 0.1-0.13-0.17 | 23.3 | 0.42 | | |
| 0.1-0.14-0.17 | 25.65 | 0.44 | 0.48 | +9 |

Just as for the L/Λ_{⊥} study, it is established that ηₛₗ ∝ηₚ. Again ηₚ varies with changes in the Jₗₑₐₖ/J ratio, but only the IFR portion of Jₗₑₐₖ,

$${J}_{l e a k}^{IFR} ,$$

varies with Δ [see Eqs. (S1a) and (S1b)]. It is found that the percentage of Jₗₑₐₖ that corresponds to

$${J}_{l e a k}^{IFR}$$

is basically constant over the range in Δ of moderately strained barriers' interfaces:

$${84}_{- 2.5}^{- 1.} \% ,$$

so its impact on the ηₛₗ value is basically the same over the 0.12-0.14 nm range in Δ. Over the same range the IOF value, defined above, and the E_{5,g4} value stay the same: 1.75×10⁻⁴ and 120 meV, respectively. Looking at Eq. (S1b),

$$1 / {τ}_{5 , g 4}^{IFR}$$

should be reasonably proportional with Δ₂ of moderately strained barriers' interfaces, given that there are different Δ values for the short and tall barriers in the AR. Looking next to the

$${J}_{l e a k}^{IFR}$$

expression [Eq. (S1a)], it is found, just as for the L/Λ_{⊥} study, that all parameters, except

$$1 / {τ}_{5 , g 4}^{IFR} ,$$

vary negligibly; thus,

$${J}_{l e a k}^{IFR}$$

is expected to be reasonably proportional with Δ². Scaling the

$${J}_{l e a k}^{IFR}$$

value for the 0.10-0.13-0.17 case with Δ², it is found from Table S7 that the errors are reasonably low: +9% and −7.7% (As discussed below, for the 8.3 μm-emitting QCL, which has a uniform A value, the errors are approximately half those found here).

Given ηₛₗ ∝ηₚ, since ηₚ=1−(Jₗₑₐₖ/J) and

$${J}_{l e a k}^{IFR}$$

is ˜84% of Jₗₑₐₖ, the ηₛₗ value variations

$$( i . e . , 5.72 W / {A}_{+ 3.9 \%}^{- 3.9 \%} )$$

can be directly attributed to variations in the Δ value of moderately strained barriers' interfaces. In short, the higher the in-plane RMS roughness is, the more IFR-triggered leakage occurs, which explains the decrease in ηₛₗ values with increasing the Δ value (of moderately strained barriers' interfaces) in Table S6.
B.2.2 8.3 μm-Emitting QCL

### B.2.2.1 Effect of Varying the Δ Value

The device that matched experimental data has a Δ value of 0.11 nm. Table S8 shows a comparison between devices of four different Δ values: 0.10 nm, 0.11 nm, 0.12 nm and 0.13 nm. The results show that the ηₛₗ value meets the criterion of +/−4% variations with respect to the value found to match experiment (i.e., 2.61 W/A for Δ=0.11 nm), for the Δ range:

$${0.11}_{- 0.01}^{+ 0.01} nm .$$

More specifically, over that range the ηₛₗ value is:

$$2.61 W / {A}_{- 1.9 \%}^{- 2.3 \%} .$$

Since ηₜᵣ is basically constant over the entire range of Δ values, ηₛₗ ∝ηₚ with negligible error (≤0.2%). The reason for this behavior can be seen from the data in Table S9.

TABLE S8
Changes in ηₛₗ with varying the Δ value.

| | Jₜₕ | Jₘₐₓ | | | Jₗₑₐₖ/ | | ηₛₗ × | |
|---|---|---|---|---|---|---|---|---|
| Δ | (kA/ | (kA/ | ηₛₗ | ηₜᵣ | Jₜₕ | ηₚ | η_{p/}ηₚ | Error |
| (nm) | cm²) | cm²) | (W/A) | (%) | (%) | (%) | (W/A) | (%) |
| 0.10 | 1.34 | 5.4 | 2.66 | 88.8 | 21.8 | 78 | 2.65 | −0.2 |
| 0.11 | 1.37 | 5.42 | 2.61 | 88.9 | 23.3 | 76.7 | | |
| 0.12 | 1.38 | 5.42 | 2.55 | 89 | 25.1 | 75 | 2.55 | 0 |
| 0.13 | 1.38 | 5.43 | 2.47 | 89 | 27.4 | 72.6 | 2.47 | 0 |

TABLE S9
$Table S 9 : Changes in the {J}_{l e a k}^{IFR} value with varying the {Δ}^{2} value .$

| Δ (nm) | ${J}_{l e a k}^{IFR} / {J}_{th} ( \% )$ | ${J}_{l eak}^{IFR} ( kA / {cm}^{2} )$ | ${J}_{l eak}^{IFR} \times {Δ}^{2} / {Δ}^{2} ( kA / {cm}^{2} )$ | Error (%) |
|---|---|---|---|---|
| 0.10 | 12.3 | 0.165 | 0.158 | −4.3 |
| 0.11 | 13.93 | 0.191 | | |
| 0.12 | 15.8 | 0.218 | 0.227 | +4.3 |
| 0.13 | 18 | 0.248 | 0.267 | +7.7 |

Just as for the other studies, since ηₛₗ ∝ηₚ one has to look at the behavior of the

$${J}_{l e a k}^{IFR}$$

portion of ηₚ as a function of the Δ value. As seen from Table S9, the

$${J}_{l e a k}^{IFR}$$

value for the Δ=0.11 nm case, when scaled with Δ² agrees with calculated values with a +/−4.3% error. Then, just as for the 4.9 μm-emitting QCL study, the conclusion is the same: the higher the in-plane RMS roughness is, the more IFR-triggered leakage occurs, which explains the decrease in ηₛₗ values with increasing Δ value (Table S8).

### B3. Summary and Conclusions

The sensitivity analysis to variations in IFR parameters on the performance of the 4.9 μm- and 8.3 μm-emitting QCLs has revealed that the slope efficiency, ηₛₗ, is the most sensitive device characteristic to variations in the L/Λ_{⊥} ratio and the in Δ values. Maximum errors of +/−4% in the ηₛₗ value have been chosen as the criterion of a reasonably good fit to experimental data.

For the 4.9 μm-emitting QCLs the acceptable range in L/Λ_{⊥} values is:

$${4}_{- 0.5}^{+ 0.5} .$$

Over that range the ηₛₗ value is:

$$5.72 W / {A}_{- 2.8 \%}^{+ 3.8 \%} .$$

The ηₛₗ value increases with increasing L/Λ_{⊥} value because of less IFR-triggered carrier leakage.

For the 8.3 μm-emitting QCL, the acceptable range in L/Λ_{⊥} values is:

$${4}_{- 1}^{+ 1} .$$

Over that range the ηₛₗ value is:

$$2.61 W / {A}_{- 3.1 \%}^{+ 2.3 \%} .$$

Just like for the 4.9 μm-emitting QCLs, the ηₛₗ value increases with increasing L/Λ_{⊥} value because of less IFR-triggered carrier leakage.

Practically, L is not likely to be wider than 0.55 nm or narrower than 0.30 nm. Thus, for the L/Λ_{⊥} value that best fits the experimental data (i.e., 4) the Λ_{⊥} value may well be in the 0.08-0.14 nm range.

For the 4.9 μm-emitting QCL, a comparison of devices of a varying Δ value (0.10/0.13/0.17 nm) vs. devices of constant Δ value (0.13 nm) revealed an ˜3% increase in the ηₛₗ value of the former over the latter, due to the low-Δ, lattice-matched barrier reducing the IFR-triggered carrier leakage.

Varying the Δ value of the moderately strained barrier:

$${0.13}_{- 0.01}^{+ 0.01} nm ,$$

leads to an the ηₛₗ value of:

$$5.72 W / {A}_{+ 3.9 \%}^{- 3.9 \%} .$$

The ηₛₗ value decreases with increasing Δ value because of increased IFR-triggered carrier leakage.

For the 8.3 μm-emitting QCL, the acceptable range in Δ values is:

$${0.11}_{- 0.01}^{+ 0.01} nm .$$

Over that range the ηₛₗ value is:

$$2.61 W / {A}_{- 1.9 \%}^{- 2.3 \%} .$$

The ηₛₗ values decrease with increasing Δ value because of increased IFR-triggered carrier leakage.

It is concluded that the ηₛₗ value variations with varying L/Λ_{⊥} and Δ values are primarily related to changes in the IFR-triggered carrier leakage. This is a critical finding, in that the ηₛₗ value is directly related to the maximum CW output power and CW wall-plug efficiency; thus, it becomes a design guideline for device-performance maximization via IFR-scattering engineering as well as via changes in crystal-growth conditions for reducing IFR-triggered carrier leakage.

C. Calculation of the Stimulated Lifetime for the 4.9 μm-Emitting QCL

The 4.9 μm-emitting QCL was found to have, at threshold, two gain spectra of similar gain peak value. For such a case, calculations of the various lifetimes, as needed to estimate the carrier-leakage current, are not only nontrivial, but cannot take into account nonlinear interactions between different lasing transitions. In turn, the relative leakage-current density at 1.4× threshold was calculated, where there is only one dominant gain peak for the transition from energy level g₄ and the lower-laser (ll) levels. However, at that drive level the laser's output power is 1.14 W; thus, there definitely exists a stimulated field which impacts lifetimes related to the lasing transition. Therefore, the stimulated lifetime, τₛₜᵢₘ, was calculated, which impacts both the lasing-transition lifetime, τ_{g4,ll}, and the global upper-level (ul) lifetime, τ_{g4,g}; i.e., the ul-level lifetime taking into account transitions to all low-energy states in the optical transition region.

For a standard 3-level laser rate equations [11], the rate of stimulated emission is:

$$S {g}_{c} {L}_{p} ( {n}_{3} - {n}_{2} ) \qquad ( S 2 )$$

where S is defined as the photon flux per period and optical transition region cross-sectional area, g_{c} is the gain cross-section, Lp is the period length, and n₃ and n₂ are the sheet carrier densities in the ul and ll levels, respectively. To characterize the rate of stimulated emission in term of a time constant:

$$S {g}_{c} {L}_{p} ( {n}_{3} - {n}_{2} ) = ( {n}_{3} - {n}_{2} ) / {τ}_{s t i m} \qquad ( S 3 )$$

where τₛₜᵢₘ is the stimulated lifetime. Thus:

$${τ}_{s t i m} = 1 / ( {Sg}_{c} {L}_{p} ) \qquad ( S 4 )$$

S can be obtained from the expression for the output power, Pₒᵤₜ:

$${P}_{out} = \frac{h c}{λ} ( 1 - R ) ( {N}_{p} W {L}_{p} ) S \qquad ( S 5 )$$

where hc/λ is the photon energy (0.258 eV in this case); Nₚ is the number of periods (40); R is front-facet power reflectivity (0.11); and W is the buried-ridge width (8 μm). Given Lₚ=43.9 nm and Pₒᵤₜ=1.14 W, S has a value of 2.203×10²⁶ photons/sec/cm². Using a calculated g_{c} value of 3.273×10⁻¹⁰ cm, from Eq. (S4) τₛₜᵢₘ=3.16 ps is obtained.
   D. Comparisons to Results Obtained with Extracted Abrupt-Interfaces IFR Parameters
   D.14.9 μm-Emitting QCL

The nextnano NEGF-based model, modified for mid-IR QCLs with parameters extracted from 4.6 μm-emitting QCLs assumed to have abrupt interfaces (Δ≅9 nm and Δ=0.12 nm) was run. The obtained L-I and V-I curves were compared to the experimental ones, and the graded-interfaces ones (data not shown). The Jₜₕ value increases from 1.3 kA/cm² to 2.2 kA/cm², since lasing starts with injection from the 1^{st}-excited injector state, level g₁, at much higher field strength: 84 kV/cm vs. 65.7 kV/cm. The emission wavelength is 4.5 μm, which hints that the laser was designed for 4.6 μm emission. Lasing ceases at a Jₘₐₓ value of 3.9 kA/cm² where state g₁ reaches resonance with state 4, the ul level. Thus, the abrupt-interfaces modeled device behaves like a conventional QCL with pocket injection, but no PICT action, in that R_{diff}=3.2Ω, and the Jₘₐₓ value is basically the same as that of conventional QCLs of same injector-doping level (i.e., ˜3.8 kA/cm²).

As for the maximum wall-plug efficiency it is, as expected, rather low: 8.5%. Unlike the PICT-action QCLs, there is no injection from a prior-stage low-energy state into the ul level, but just conventional resonant-tunneling injection from a low-energy injector state into the ul level. Notably, at resonance there is a large splitting energy (13 meV); that is, strong coupling, but this shows that strong coupling is not enough to achieve PICT action.

D.2 8.3 μm-Emitting QCL

The nextnano NEGF-based model, modified for mid-IR QCLs, with parameters extracted from an 8.5 μm-emitting QCLs assumed to have abrupt interfaces (Λ=9 nm and Δ=0.10 nm) was run. The obtained L-I and V-I curves were compared to the experimental ones, and to the graded-interfaces ones (data not shown). J_{th increases} from 1.37 kA/cm² to 1.98 kA/cm², since lasing starts with injection from a state below state 2 of the prior stage (i.e., from state 2′) into level g₂, thus at a higher field: 46.6 kV/cm vs. 42.5 kV/cm, compared to injection from state 2 into level 4 in the graded-interfaces case. There is PICT action, but it is significantly weaker than for the graded-interfaces case, as evidenced by a higher R_{diff} value: 1.9Ω vs. 1.6Ω, and a lower Jₘₐₓ value: 5.2 kA/cm² vs. 5.45 kA/cm². The slope efficiency is also lower: 2.2 W/A vs. 2.6 W/A, due to higher relative carrier leakage (i.e., 37.6% vs. 23.3%). Thus, the maximum wall-plug efficiency: 10%, is significantly lower than for the graded interfaces case: 17%.

### Example 2

The CB diagram and relevant wavefunctions are shown in FIG. 17 for an illustrative 4.7 μm-emitting STA type QCL according to the present disclosure. The inventors' modified NEGF-based analysis was conducted for this structure using the IFR parameters found above for the 4.9 μm-emitting GSMBE-grown QCL. Considering optimized crystal growth conditions to obtain a_{w}=0.5 cm⁻¹, Jₗₑₐₖ/J was found to be 13.5% for the device. As shown in FIG. 18, a buried heterostructure (BH) device of same dimensions as the 4.9 μm-emitting QCL results in a WPE value of 33%, which to the inventors' knowledge, is the highest projected WPE for a mid-IR QCL to date. Further suppression of carrier leakage as described herein will lead to WPE values even closer to 40%.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the disclosure has been presented for purposes of illustration and of description. It is not intended to be exhaustive or to limit the disclosure to the precise form disclosed, and modifications and variations are possible in light of the above teachings or may be acquired from practice of the disclosure. The embodiments were chosen and described in order to explain the principles of the disclosure and as practical applications of the disclosure to enable one skilled in the art to utilize the disclosure in various embodiments and with various modifications as suited to the particular use contemplated. It is intended that the scope of the disclosure be defined by the claims appended hereto and their equivalents.

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

Terms such as “comprising” and the like may be replaced with terms such as “consisting” and the like.

What is claimed is:

1. A quantum cascade laser (QCL) comprising a plurality of stages, each stage comprising alternating quantum well layers and barrier layers, wherein each stage is configured, upon application of an electric field F across the plurality of stages, to inject carriers from a low energy state of an adjacent, upstream stage of the plurality of stages into a high energy state of a lasing stage of the plurality of stages, via tunneling injection through multiple barrier layers comprising barrier layers of the adjacent, upstream stage and barrier layers of the lasing stage, wherein carriers in the lasing stage undergo intraband transitions from an upper laser level of the lasing stage to at least one lower laser level of the lasing stage with the emission of laser light and without carrier leakage.

2. The QCL of claim 1, wherein a wavefunction corresponding to the low energy state and a wavefunction corresponding to the high energy state have a resonance point Fᵣₑₛ above a lasing-threshold field Fₜₕ for the QCL.

3. The QCL of claim 1, wherein the multiple barrier layers comprise at least 7 barrier layers.

4. The QCL of claim 1, wherein the high energy state is the upper laser level such that the carriers are injected via direct carrier injection.

5. The QCL of claim 1, wherein the low energy state is the upper laser level.

6. The QCL of claim 1, wherein each stage is configured to achieve sequential interstage carrier injection.

7. The QCL of claim 6, wherein sequential interstage carrier injection comprises an initial interstage carrier injection step and additional interstage carrier injection steps.

8. The QCL of claim 7, wherein the initial interstage carrier injection step and the additional interstage carrier injection steps are direct carrier injection steps.

9. The QCL of claim 7, wherein only the additional interstage carrier injection steps are direct carrier injection steps.

10. The QCL of claim 1, wherein each stage is configured such that the low energy state and the high energy state have a splitting energy at their resonance point of at least 5 meV.

11. The QCL of claim 1, wherein each stage is configured to exhibit photon-induced carrier transport.

12. The QCL of claim 11, wherein each stage is configured such that the low energy state and the high energy state have a splitting energy at their resonance point of at least 5 meV; wherein each stage is configured such that an overall dipole matrix element for the upper laser level and the lower laser level is less than 10 Å; and further wherein each stage is configured such that a global lifetime of the lower laser level is no more than 0.15 ps.

13. The QCL of claim 1, wherein each stage is configured such that an interface overlap factor for the upper laser level and an adjacent high energy state of the lasing stage is no more than 10⁻⁴.

14. The QCL of claim 1, wherein each stage is configured such that a ratio of graded-interface width to axial correlation length L/Λ_{⊥} for each stage is at least 4.

15. The QCL of claim 1, wherein each stage is configured such that a root-mean square height Δ for each stage is no more than 0.20 nm.

16. The QCL of claim 13, wherein each stage is configured such that a ratio of graded-interface width to axial correlation length L/Λ_{⊥} for each stage is at least 4; and further wherein each stage is configured such that a root-mean square height Δ for each stage is no more than 0.20 nm.

17. The QCL of claim 1, wherein each stage is configured such that the QCL is characterized by a normalized leakage-current density Jₗₑₐₖ/J value of no more than 20%.

18. The QCL of claim 17, wherein each stage is configured such that a ratio of graded-interface width to axial correlation length L/Λ_{⊥} for each stage is at least 4; and further wherein each stage is configured such that a root-mean square height Δ for each stage is no more than 0.20 nm.

19. The QCL of claim 11, wherein the laser light has a wavelength in a range of from 4 μm to 6 μm and wherein each stage is configured such that the QCL is characterized by a wall-plug efficiency at room temperature of at least 33%.

20. The QCL of claim 11, wherein the laser light has a wavelength in a range of from 7 μm to 10 μm and wherein each stage is configured such that the QCL is characterized by a wall-plug efficiency at room temperature of at least 22%.
